(19) United States
(12) Patent Application Publication
(10) Pub. No.: US 2023/0413500 A1
(43) Pub. Date: Dec. 21, 2023

(54) METALLIC BASED ELECTROMAGNETIC INTERFERENCE SHIELDING MATERIALS, DEVICES, AND METHODS OF MANUFACTURE THEREOF

(71) Applicant: NANOTECH ENERGY, INC., Sunny Isles Beach, FL (US)

(72) Inventors: Maher F. EL-KADY, Los Angeles, CA (US); Jack KAVANAUGH, Los Angeles, CA (US); Richard B. KANER, Pacific Palisades, CA (US); Scott LAINE, Chico, CA (US)

(21) Appl. No.: 18/459,294

(22) Filed: Aug. 31, 2023

Related U.S. Application Data
(63) Continuation of application No. PCT/US2021/060839, filed on Nov. 24, 2021.
(60) Provisional application No. 63/118,533, filed on Nov. 25, 2020.

(51) Int. Cl. H05K 9/00; C09D 5/32; C09D 5/24; C09D 7/62; C09D 7/40; C09D 7/63

(52) U.S. Cl. CPC H05K 9/0083; C09D 5/32; C09D 5/24; C09D 7/62; C09D 7/67; C09D 7/63

(57) ABSTRACT

Described are EMI shields comprising a substrate, a metal-based conductive additive, and a binder incorporated with the conductive additive and deposited on the substrate, and methods of making thereof. In some embodiments, a carbon-based additive is included to enhance the mechanical properties and/or conductivity of the EMI shield.

### CROSS-REFERENCE

This application is a continuation application of International Application No. PCT/US2021/060839 filed Nov. 24, 2021, which claims the benefit of U.S. Provisional Application No. 63/118,533, filed Nov. 25, 2020, which are hereby incorporated by reference in their entirety herein.

### BACKGROUND

Electromagnetic interference (EMI) is a signal received from a natural or man-made external source that is unwanted. Such EMI can and negatively affect the performance of electrical component through electromagnetic induction, electrostatic coupling, or conduction provided thereby. These electronic disturbances can degrade the performance of computing and communication components by increasing the error rates in data transfer and storage. EMI shielding, however, can protect electrical devices from external signal interference, from leaking EMI signals, and to prevent electrical components within an electrical device from interfering with each other. Shielding from EMI is also important to ensure accurate testing and calibration of electronic components.

### SUMMARY

Disclosed herein are EMI shields or shielding materials that provide numerous advantages over conventional EMI shields. The high thermal and electrical conductivity of the EMI shields herein efficiently dissipate heat energy and minimize EMI interference, even at low thicknesses. Further, unlike conventional metal foils, the EMI shielding materials herein are lightweight and exhibit excellent mechanical flexibility, structural integrity, high corrosion resistance, and can be easily applied to a wide variety of enclosures. Further, in contrast to standard metal-based EMI shielding, the EMI shielding materials herein can be easily cut and applied to surfaces, and withstand repeated bending without fatigue or performance degradation.

In some embodiments, the EMI shielding materials herein comprise a metal-based conductive additive. In some embodiments, the metal-based conductive additive comprises a nanomaterial (e.g. metallic nanoflakes). In some embodiments, the EMI shielding materials herein further comprises a carbon or carbon-based additive such as, for example, graphene or graphene framework. In some embodiments, the graphene has a morphology of carbon sheets that are exfoliated, expanded, or separated from each other, and which are interconnected to form a single electrically linked conductive network. In some embodiments, the carbon or carbon-based additive comprises a 3-dimensional network of interconnected carbon sheets with high surface area and conductivity. Accordingly, the morphology of the carbon or carbon-based additive herein confers high conductivity throughout the EMI shielding material by forming a scaffolding that contains and connects the metal-based conductive additives within. Moreover, this framework enables the enhanced mechanical properties of the EMI shielding materials herein. By contrast, separated and distinct single graphene sheets may lack the connectivity to provide high conductivity throughout a single network. Finally, in comparison with conventional EMI shields, the EMI shielding materials of the present disclosure are easily prepared and applied at various thicknesses and sizes on a variety of substrates to achieve the desired shielding properties. For example, a thicker application of the EMI shielding materials herein allow greater EMI reduction for more sensitive electronics.

One aspect provided herein is an EMI shield comprising: a substrate; a metal-based conductive additive; and a binder incorporated with the metal-based conductive additive and deposited as an EMI shielding coating on the substrate.

In some embodiments, the substrate comprises plastic, metal, glass, or any combination thereof. In some embodiments, the metal comprises a ferrous metal, a non-ferrous metal, a coated surface, plastic, fiberglass, stainless steel, or wood. In some embodiments, the metal comprises copper, aluminum, steel, stainless steel, beryllium, bismuth, chromium, cobalt, gallium, gold, indium, iron, lead, magnesium, nickel, silver, titanium, tin, zinc, or any combination thereof. In some embodiments, the plastic comprises a thermoplastic polymer. In some embodiments, the thermoplastic comprises polyethylene terephthalate, polyglycolic acid, polylactic acid, polycaprolactone, polyhydroxyalkanoate, polyhydroxybutyrate, polyethylene adipate, polybutylene succinate, poly(3-hydroxybutyrate-co-3-hydroxyvalerate), polybutylene terephthalate, polytrimethylene terephthalate, polyethylene naphthalate, or any combination thereof. In some embodiments, the metal-based conductive additive is a metallic nanomaterial comprising nickel, copper, silver, nickel, zinc, aluminum, tin, or gold. In some embodiments, the metallic nanomaterial comprises a first metal forming a metallic core and a second metal forming a coating around the metallic core. In some embodiments, the first metal comprises aluminum, nickel, copper, or iron, and the second metal comprises silver. In some embodiments, the metallic nanomaterial comprises a morphology comprising nanoparticles, nanorods, nanowires, nanoflowers, nanoflakes, nanofibers, nanoplatelets, nanoribbons, nanocubes, bipyramids, nanodiscs, nanoplates, nanodendrites, nanoleaves, nanospheres, quantum spheres, quantum dots, nanosprings, nanosheets, porous nanosheets, nanomesh, or any combination thereof. In some embodiments, a w/w concentration of the metal-based conductive additive in the EMI shielding coating is about 5% to about 95%. In some embodiments, a w/w concentration of the binder in the EMI shielding coating is about 20% to about 95%. In some embodiments, binder comprises an alkyd, an acrylic, a vinyl-acrylic, vinyl acetate/ethylene (VAE), polyurethane, polyethylene, polyester, styrene, styrene acrylic, melamine, a silane, a siloxane, or any combination thereof. In some embodiments, the EMI shielding coating further comprises a coating thinner. In some embodiments, the coating thinner comprises acetone, 4-chloro-alpha, alpha, or alpha-trifluorotoluene. In some embodiments, a w/w concentration of the coating thinner in the EMI shielding coating is about 5% to about 90%. In some embodiments, the EMI shielding coating further comprises a viscosity modifier. In some embodiments, the viscosity modifier comprises Acetone, N-Methyl-2-pyrrolidone (NMP), Ethanol, Xylene, Petroleum, N-butyl acetate, Heptan-2-one, 4-isocyanatosulphonyltoluene, 2-Methoxy-1-methylethyl acetate, or combinations thereof. In some embodiments, the EMI shielding coating further comprises a carbon-based additive. In some embodiments, a w/w concentration of the carbon-based additive in the EMI shielding coating is about 0.01% to about 5%. In some embodiments, the carbon-based additive comprises graphite, graphene, reduced graphene, carbon black, cabot carbon, a carbon nanotube, a functionalized carbon nanotube, or any combination thereof. In some embodiments, at least one of the graphene and the graphene oxide has a specific surface area of greater than 1,000 m²/g. In some embodiments, at least one of the graphene and the graphene oxide has a conductivity of about 1,000 S/m to about 4,000 S/m. In some embodiments, the carbon nanotube has an electrical conductivity of greater than about 100 S/In some embodiments, the carbon-based additive has a mean particle size of about 2 um to about 30 um. In some embodiments, the carbon-based additive has a specific surface area of about 2 m²/g to about 16 m²/g. In some embodiments the EMI shield has a conductivity of about 10 S/m to about 20,000 S/m. In some embodiments the EMI shield has a sheet resistance of about 0.1 ohm/sq to about 1,000 ohm/sq. In some embodiments the EMI shield has an operating temperature of at about 0° C. to about 400° C. In some embodiments, the EMI shielding coating has a thickness of about 10 um to about 1,000 um. In some embodiments the EMI shield has a shielding effectiveness in the frequency range of about 10 kHz to about 400 kHz of about 20 dB to about 100 dB with an EMI shielding coating thickness of less than about 150 um. In some embodiments the EMI shield has a shielding effectiveness in the frequency range of about 500 kHz to about 30 MHz of about 20 dB to about 100 dB with an EMI shielding coating thickness of less than about 150 um. In some embodiments the EMI shield has a shielding effectiveness in the frequency range of about 40 MHz to about 1 GHz of about 10 dB to about 100 dB with a film thickness of less than about 150 um. In some embodiments the EMI shield has a shielding effectiveness in the frequency range of 2 GHz to 18 GHz of about 30 dB to about 120 dB with a film thickness of less than about 150 um. In some embodiments the EMI shield has a shielding effectiveness in the frequency range of 19 GHz to 40 GHz of about 50 dB to about 130 dB with a film thickness of less than about 150 um.

Another aspect provided herein is an EMI shielding coating comprising: a metal-based conductive additive; a binder; and a solvent incorporated with the metal-based conductive additive and binder to form the EMI shielding coating.

In some embodiments, the EMI shielding coating comprises a clearcoat coating and an activator coating, wherein mixing the clearcoat coating and the activator coating causes the EMI shielding coating to cure. In some embodiments, the clear coating and the activator coating have a viscosity of about 25 cP to about 8,000 cP. In some embodiments, the metal-based conductive additive is a metallic nanomaterial comprising nickel, copper, silver, nickel, zinc, aluminum, tin, or gold. In some embodiments, the metallic nanomaterial comprises a first metal forming a metallic core and a second metal forming a coating around the metallic core. In some embodiments, the first metal comprises aluminum, nickel, copper, or iron, and the second metal comprises silver. In some embodiments, the metallic nanomaterial comprises a morphology comprising nanoparticles, nanorods, nanowires, nanoflowers, nanoflakes, nanofibers, nanoplatelets, nanoribbons, nanocubes, bipyramids, nanodiscs, nanoplates, nanodendrites, nanoleaves, nanospheres, quantum spheres, quantum dots, nanosprings, nanosheets, porous nanosheets, nanomesh, or any combination thereof. In some embodiments, a w/w concentration of the metal-based conductive additive in the EMI shielding coating is about 5% to about 95%. In some embodiments, a w/w concentration of the binder in the EMI shielding coating is about 20% to about 95%. In some embodiments, binder comprises an alkyd, an acrylic, a vinyl-acrylic, vinyl acetate/ethylene (VAE), polyurethane, polyethylene, polyester, styrene, styrene acrylic, melamine, a silane, a siloxane, or any combination thereof. In some embodiments, the EMI shielding coating further comprises a coating thinner. In some embodiments, the coating thinner comprises acetone, 4-chloro-alpha, alpha, or alpha-trifluorotoluene. In some embodiments, a w/w concentration of the coating thinner in the EMI shielding coating is about 5% to about 90%. In some embodiments, the EMI shielding coating further comprises a viscosity modifier. In some embodiments, the viscosity modifier comprises Acetone, N-Methyl-2-pyrrolidone (NMP), Ethanol, Xylene, Petroleum, N-butyl acetate, Heptan-2-one, 4-isocyanatosulphonyltoluene, 2-Methoxy-1-methylethyl acetate, or combinations thereof. In some embodiments, the EMI shielding coating further comprises a carbon-based additive. In some embodiments, a w/w concentration of the carbon-based additive in the EMI shielding coating is about 0.01% to about 5%. In some embodiments, the carbon-based additive comprises graphite, graphene, reduced graphene, carbon black, cabot carbon, a carbon nanotube, a functionalized carbon nanotube, or any combination thereof. In some embodiments, at least one of the graphene and the graphene oxide has a specific surface area of greater than 1,000 m²/g. In some embodiments, at least one of the graphene and the graphene oxide has a conductivity of about 1,000 S/m to about 4,000 S/m. In some embodiments, the carbon nanotube has an electrical conductivity of greater than about 100 S/cm. In some embodiments, the carbon-based additive has a mean particle size of about 2 um to about 30 um. In some embodiments, the carbon-based additive has a specific surface area of about 2 m²/g to about 16 m²/g. In some embodiments, the EMI shielding coating has a conductivity of about 10 S/m to about 20,000 S/m. In some embodiments, the EMI shielding coating has a sheet resistance of about 0.1 ohm/sq to about 1,000 ohm/sq. In some embodiments, the EMI shielding coating has an operating temperature of at about 0° C. to about 400° C. In some embodiments, the EMI shielding coating has a thickness of about 10 um to about 1,000 um. In some embodiments, the EMI shielding coating has a shielding effectiveness in the frequency range of about 10 kHz to about 400 kHz of about 20 dB to about 100 dB with an EMI shielding coating thickness of less than about 150 um. In some embodiments, the EMI shielding coating has a shielding effectiveness in the frequency range of about 500 kHz to about MHz of about 20 dB to about 100 dB with an EMI shielding coating thickness of less than about 150 um. In some embodiments, the EMI shielding coating has a shielding effectiveness in the frequency range of about 40 MHz to about 1 GHz of about 10 dB to about 100 dB with a film thickness of less than about 150 um. In some embodiments, the EMI shielding coating has a shielding effectiveness in the frequency range of 2 GHz to 18 GHz of about 30 dB to about 120 dB with a film thickness of less than about 150 um. In some embodiments, the EMI shielding coating has a shielding effectiveness in the frequency range of 19 GHz to 40 GHz of about 50 dB to about 130 dB with a film thickness of less than about 150 um.

Another aspect provided herein is a method of forming an EMI shield comprising: forming a coating comprising a metal-based conductive additive, a binder, and a solvent; depositing the coating on a substrate; and drying the coating on the substrate to form an EMI shielding coating.

In some embodiments, a set thickness of the coating is deposited on the substrate. In some embodiments, drying the coating on the substrate comprises drying at a temperature of about 20° C. to about 120° C. In some embodiments, the forming of the coating comprises: mixing the coating; breaking down agglomerates in the coating; removing air bubbles from the coating; or any combination thereof. In some embodiments, the mixing is performed by an acoustic mixer. In some embodiments, the breaking down of the agglomerates in the coating is performed by a high shear mixer. In some embodiments, the removing of the air bubbles from the coating is performed by a vacuum mixer. In some embodiments, depositing the coating on a substrate comprises depositing the coating on the substrate with a coating machine. In some embodiments, the coating machine is a slot die coating machine. In some embodiments, at least one of the breaking down of the agglomerates in the coating and the removing of the air bubbles from the coating is performed until the coating has a viscosity of about 25 cP to about 8,000 cP. In some embodiments, the coating has a viscosity of about 25 cP to about 8,000 cP. In some embodiments, the method further comprises calendaring the EMI shield. In some embodiments, calendaring is performed by a roll to roll calendaring machine. In some embodiments, the EMI shield has a conductivity of about 10 S/m to about 20,000 S/m. In some embodiments, the EMI shield has a sheet resistance of about 0.1 ohm/sq to about 1,000 ohm/sq. In some embodiments, the EMI shield has an operating temperature of at about 0° C. to about 400° C. In some embodiments, the EMI shield has a thickness of about 10 um to about 1,000 um.

Another aspect provided herein is a method of forming an EMI shield, comprising: obtaining a coating comprising a metal-based conductive additive, a binder, and a solvent; applying the coating onto a substrate; and drying the coating on the substrate to form an EMI shielding coating.

In some embodiments, obtaining the coating comprises mixing a clearcoat coating and an activator coating, wherein the clearcoat coating and the activator coating both comprise the metal-based conductive additive, the binder, and the solvent, wherein the activator coating further comprises an activator for curing the coating. In some embodiments, the coating is applied onto the substrate by spraying. In some embodiments, the coating is applied onto the substrate by air spraying. In some embodiments, the EMI shielding coating comprises a clearcoat coating and an activator coating, wherein mixing the clearcoat coating and the activator coating causes the EMI shielding coating to cure. In some embodiments, the clear coating and the activator coating have a viscosity of about 25 cP to about 8,000 cP. In some embodiments, the metal-based conductive additive is a metallic nanomaterial comprising nickel, copper, silver, nickel, zinc, aluminum, tin, or gold. In some embodiments, the metallic nanomaterial comprises a first metal forming a metallic core and a second metal forming a coating around the metallic core. In some embodiments, the first metal comprises aluminum, nickel, copper, or iron, and the second metal comprises silver. In some embodiments, the metallic nanomaterial comprises a morphology comprising nanoparticles, nanorods, nanowires, nanoflowers, nanoflakes, nanofibers, nanoplatelets, nanoribbons, nanocubes, bipyramids, nanodiscs, nanoplates, nanodendrites, nanoleaves, nanospheres, quantum spheres, quantum dots, nanosprings, nanosheets, porous nanosheets, nanomesh, or any combination thereof. In some embodiments, a w/w concentration of the metal-based conductive additive in the EMI shielding coating is about 5% to about 95%. In some embodiments, a w/w concentration of the binder in the EMI shielding coating is about 20% to about 95%. In some embodiments, binder comprises an alkyd, an acrylic, a vinyl-acrylic, vinyl acetate/ethylene (VAE), polyurethane, polyethylene, polyester, styrene, styrene acrylic, melamine, a silane, a siloxane, or any combination thereof. In some embodiments, the EMI shielding coating further comprises a coating thinner. In some embodiments, the coating thinner comprises acetone, 4-chloro-alpha, alpha, or alpha-trifluorotoluene. In some embodiments, a w/w concentration of the coating thinner in the EMI shielding coating is about 5% to about 90%. In some embodiments, the EMI shielding coating further comprises a viscosity modifier. In some embodiments, the viscosity modifier comprises Acetone, N-Methyl-2-pyrrolidone (NMP), Ethanol, Xylene, Petroleum, N-butyl acetate, Heptan-2-one, 4-isocyanatosulphonyltoluene, 2-Methoxy-1-methylethyl acetate, or combinations thereof. In some embodiments, the EMI shielding coating further comprises a carbon-based additive. In some embodiments, a w/w concentration of the carbon-based additive in the EMI shielding coating is about 0.01% to about 5%. In some embodiments, the carbon-based additive comprises graphite, graphene, reduced graphene, carbon black, cabot carbon, a carbon nanotube, a functionalized carbon nanotube, or any combination thereof. In some embodiments, at least one of the graphene and the graphene oxide has a specific surface area of greater than 1,000 m²/g. In some embodiments, at least one of the graphene and the graphene oxide has a conductivity of about 1,000 S/m to about 4,000 S/m. In some embodiments, the carbon nanotube has an electrical conductivity of greater than about 100 S/cm. In some embodiments, the carbon-based additive has a mean particle size of about 2 um to about 30 um. In some embodiments, the carbon-based additive has a specific surface area of about 2 m²/g to about 16 m²/g. In some embodiments, the EMI shield has a conductivity of about 10 S/m to about 20,000 S/m. In some embodiments, the EMI shield has a sheet resistance of about 0.1 ohm/sq to about 1,000 ohm/sq. In some embodiments, the EMI shield has an operating temperature of at about 0° C. to about 400° C. In some embodiments, the EMI shielding coating has a thickness of about 10 um to about 1,000 um. In some embodiments, the EMI shield has a shielding effectiveness in the frequency range of about 10 kHz to about 400 kHz of about 20 dB to about 100 dB with an EMI shielding coating thickness of less than about 150 um. In some embodiments, the EMI shield has a shielding effectiveness in the frequency range of about 500 kHz to about 30 MHz of about 20 dB to about 100 dB with an EMI shielding coating thickness of less than about 150 um. In some embodiments, the EMI shield has a shielding effectiveness in the frequency range of about 40 MHz to about 1 GHz of about 10 dB to about 100 dB with a film thickness of less than about 150 um. In some embodiments, the EMI shield has a shielding effectiveness in the frequency range of 2 GHz to 18 GHz of about 30 dB to about 120 dB with a film thickness of less than about 150 um. In some embodiments, the EMI shield has a shielding effectiveness in the frequency range of 19 GHz to 40 GHz of about 50 dB to about 130 dB with a film thickness of less than about 150 um.

Another aspect provided herein is an EMI shield comprising: a substrate; a metal-based conductive additive; a carbon-based additive; and a binder incorporated with the metal-based conductive additive and the carbon-based additive and deposited as an EMI shielding coating on the substrate.

In some embodiments, a w/w concentration of the carbon-based additive in the EMI shielding coating is about 0.01% to about 5%. In some embodiments, the carbon-based additive comprises graphite, graphene, reduced graphene, carbon black, cabot carbon, a carbon nanotube, a functionalized carbon nanotube, or any combination thereof. In some embodiments, at least one of the graphene and the graphene oxide has a specific surface area of greater than 1,000 m²/g. In some embodiments, at least one of the graphene and the graphene oxide has a conductivity of about 1,000 S/m to about 4,000 S/m. In some embodiments, the carbon nanotube has an electrical conductivity of greater than about 100 S/cm. In some embodiments, the carbon-based additive has a mean particle size of about 2 um to about 30 um. In some embodiments, the carbon-based additive has a specific surface area of about 2 m²/g to about 16 m²/g.

### BRIEF DESCRIPTION OF THE DRAWINGS

The novel features of the disclosure are set forth with particularity in the appended claims. A better understanding of the features and advantages of the present disclosure will be obtained by reference to the following detailed description that sets forth illustrative embodiments, in which the principles of the disclosure are utilized, and the accompanying drawings of which:

FIG. 1 is a diagram of the reflection and absorption in an Electromagnetic Interference (EMI) shield, per an embodiment herein;

FIG. 2 shows a diagram of an EMI shield effectiveness testing setup, per an embodiment herein;

FIG. 3A shows an image of a first exemplary EMI shields, per an embodiment herein;

FIG. 3B shows an image of a second exemplary EMI shields, per an embodiment herein;

FIG. 3C shows an image of a third exemplary EMI shields, per an embodiment herein;

FIG. 4 shows a shielding effectiveness graph of a first exemplary EMI shielding coating, per an embodiment herein;

FIG. 5 shows a shielding effectiveness graph of an exemplary second EMI shielding coating, per an embodiment herein;

FIG. 6 shows a shielding effectiveness graph of an exemplary third EMI shielding coating, per an embodiment herein;

FIG. 7 shows a shielding effectiveness graph of an exemplary first EMI shield, per an embodiment herein;

FIG. 8 shows a shielding effectiveness graph of an exemplary second EMI shield, per an embodiment herein;

FIG. 9 shows a shielding effectiveness graph of an exemplary third EMI shield, per an embodiment herein;

FIG. 10 shows an XRD (X-Ray Diffraction) graph for an exemplary metal-based conductive additive, per an embodiment herein;

FIG. 11 shows a schematic illustration of an exemplary EMI shielding coating, per an embodiment herein;

FIG. 12 shows a schematic illustration of an exemplary EMI shield, per an embodiment herein;

FIG. 13A shows a scanning electron microscope (SEM) image of an exemplary fourth EMI shield, per an embodiment herein;

FIG. 13B shows a high magnification SEM image of an exemplary fourth EMI shield, per an embodiment herein;

FIG. 14A shows a microscope image of an exemplary fourth EMI shield, per an embodiment herein;

FIG. 14B shows a high magnification microscope image of an exemplary fourth EMI shield, per an embodiment herein;

FIG. 15A shows a two-dimensional height map of an exemplary fourth EMI shield, per an embodiment herein;

FIG. 15B shows a three-dimensional height map of an exemplary fourth EMI shield, per an embodiment herein;

FIG. 16 shows a graph of heat flow and weight of an exemplary fourth EMI shield as a function of temperature, per an embodiment herein;

FIG. 17A shows an SEM image of an exemplary fifth EMI shield formed by spray coating, per an embodiment herein;

FIG. 17B shows a high magnification SEM image of an exemplary fifth EMI shield formed by spray coating, per an embodiment herein;

FIG. 18A shows a two-dimensional height map of an exemplary fifth EMI shield formed by spray coating, per an embodiment herein;

FIG. 18B shows a three-dimensional height map of an exemplary fifth EMI shield formed by spray coating, per an embodiment herein;

FIG. 19A shows an SEM image of an exemplary fifth EMI shield formed with a doctors blade, per an embodiment herein;

FIG. 19B shows a high magnification SEM image of an exemplary fifth EMI shield formed with a doctors blade, per an embodiment herein;

FIG. 20A shows a two-dimensional height map of an exemplary fifth EMI shield formed with a doctors blade, per an embodiment herein;

FIG. 20B shows a three-dimensional height map of an exemplary fifth EMI shield formed by spray coating, per an embodiment herein;

FIG. 21 shows a graph of heat flow and weight of an exemplary fifth EMI shield as a function of temperature, per an embodiment herein;

FIG. 22A shows an SEM image of an exemplary sixth EMI shield, per an embodiment herein;

FIG. 22B shows a high magnification SEM image of an exemplary sixth EMI shield, per an embodiment herein;

FIG. 23A shows a microscope image of an exemplary sixth EMI shield, per an embodiment herein;

FIG. 23B shows a high magnification microscope image of an exemplary sixth EMI shield, per an embodiment herein;

FIG. 24A shows a two-dimensional height map of an exemplary sixth EMI shield, per an embodiment herein;

FIG. 24B shows a three-dimensional height map of an exemplary sixth EMI shield, per an embodiment herein;

FIG. 25 shows a graph of heat flow and weight of an exemplary sixth EMI shield as a function of temperature, per an embodiment herein;

FIG. 26 shows a graph of the conductivities of exemplary fourth, fifth, and sixth EMI shield samples, per an embodiment herein; and

FIG. 27 shows a graph of the shielding effectiveness vs. frequency for exemplary fourth, fifth, and sixth EMI shield samples, per an embodiment herein.

### DETAILED DESCRIPTION

Provided herein are carbon-based electromagnetic interference (EMI) shielding devices and shielding materials, and preparation methods thereof. In some embodiments, the EMI shielding coatings and shields herein enable the isolation of an electrical device from external radio frequency signals during testing and/or operation. In some embodiments, the EMI shielding coatings and shields herein prevent radio frequency signals generated by an electrical device from escaping an enclosure. In some embodiments, the EMI shielding coatings and shields herein prevent radio frequency cross-talk or interference between two or more electrical devices.

In some embodiments, the EMI shielding devices are formed by a coating deposited on a substrate. In some embodiments, the EMI shielding devices are formed with compression molding techniques. The EMI shielding devices can be shaped from one or more sheets. The sheets can be thin, flexible, lightweight, and/or corrosion resistant. The EMI shielding materials can be adapted to provide EMI shielding or filtering according to the desired effect. As an example, an EMI shield can be shaped as an enclosure (e.g., a box shape enclosing sensitive electronics). As another example, EMI shielding materials can be cut into thin, flexible sheets sized to the walls of a room, and then applied to the walls, optionally with an adhesive on one side of the sheets, in order to generate an EMI shielded room. Accordingly, the various advantages of the present disclosure include allowing EMI shielding to be efficiently adapted to devices, rooms, vehicles, or other relevant implementations, even when such implementations were not designed for or even originally contemplate EMI shielding.

The EMI shielding coatings and shields herein can be applied to an interior surface of an electrical enclosure, to efficiently attenuate electromagnetic interference (EMI) with or between electrical components therein. The EMI shielding coatings and shields herein can be applied to an interior surface of an electrical enclosure, to provide corrosion resistance, abrasion protection and heat dissipation. In some embodiments, the EMI shielding coatings and shields herein can used to replace and/or supplement existing shielding or conductive coatings and shields.

In some embodiments, the high conductivity of the EMI shielding coatings and shields herein provide maximum external EMI/RFI protection for equipment enclosed thereby. In some embodiments, the high conductivity of the EMI shielding coatings and shields herein prevent internal EMI/RFI leaking into the environment. In some embodiments, the high thermal conductivity of the EMI shielding coatings and shields herein enable its use as a heat sink for an electrical component.

While many EMI shielding materials employ metals such as copper for their with high conductivities, forming metal-based coatings and shields is often difficult. Further, as such materials are susceptible to chemical corrosions and oxidations, which form an insulating oxide layer, the efficacy of these EMI shields often wanes over time. While silver-based EMI shields exhibit high electrical conductivity and oxidation/corrosion resistance, its use is cost prohibitive for most applications.

As such, provided herein in some embodiments are EMI shielding coatings and EMI shields comprising silver-coated copper (Ag—Cu) powders, which exhibit a high conductivity and corrosion/oxidation resistance. Further, the reduced quantities of expensive silver enables the use of the EMI shielding coatings and EMI shields herein for a variety of applications.

The EMI shielding coatings and the EMI shields made therefrom exhibit high conductivities of at least about 1000 S/cm. Further the 50-100 um thick EMI shields further exhibit an impressive EMI attenuation of at least about 50 dB at a frequency range of 10 kHz to 40 MHz, and at least about 60 dB in the 1 GHz to 40 GHz frequency range. a shielding effectiveness of 50-80 decibels (dB) can be easily achieved with films of 50-100 um thick.

### EMI Shielding Mechanics

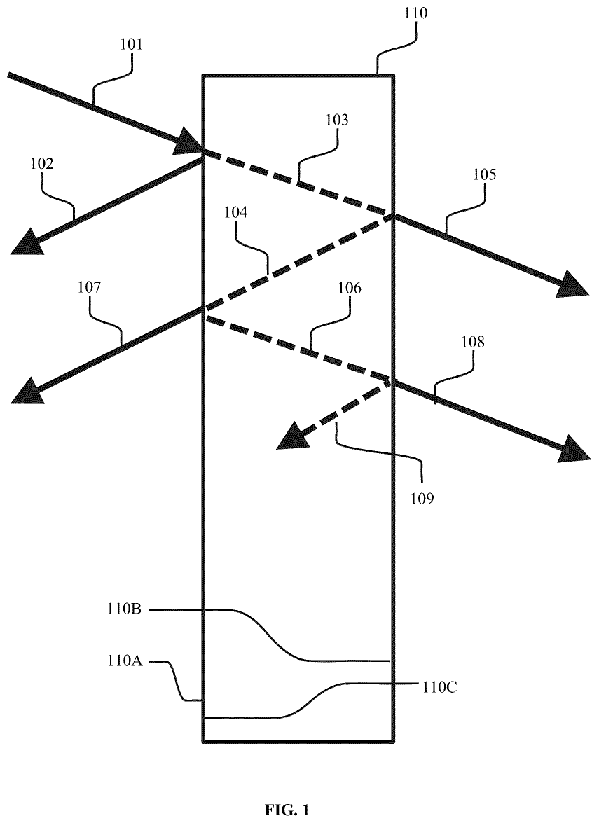

FIG. 1 shows a diagram of the reflection and absorption in an Electromagnetic Interference (EMI) shield 110. As shown therein, a first externally reflected portion (e.g., a d-wave reflectance) 102 of an incident t-wave 101 is reflected by an outer proximal surface 110A of the EMI shield, whereas an absorbed portion 103 of the t-wave 101 is absorbed into the EMI shield. A first internally reflected portion 104 of the absorbed portion 103 reflects off an interior distal surface 110B of the EMI shield 110 wherein a first attenuated portion 105 of the first absorbed portion 103 is transmitted distally through the EMI shield 110. Thereafter, a second internally reflected portion 106 of the first internally reflected portion 104 reflects off an interior proximal surface 110C of the EMI shield 110 wherein a second externally reflected portion 107 of the first internally reflected portion 104 is transmitted proximally towards the source of the incident t-wave 101 and parallel to the first externally reflected portion 102. The internal reflection continues as a third internally reflected portion 109 of the second internally reflected portion 106 reflects off an interior distal surface 110B of the EMI shield 110 wherein a second attenuated portion 108 of the second internally reflected portion 106 is transmitted distally into the EMI shield 110.

In some embodiments, the effectiveness of the EMI 110 shield correlates to a ratio between a strength the incident t-wave 101 and the sum of the strengths of the first attenuated portion 105 and the second attenuated portion 108. In some embodiments, the effectiveness of the EMI 110 shield correlates to a ratio between the sum of the strengths of the first externally reflected portion 102 and the second externally reflected portion 107 and the sum of the strengths of the first attenuated portion 105 and the second attenuated portion 108. In some embodiments, the effectiveness of the EMI 110 shield correlates to a ratio between the sum of the strengths of the first externally reflected portion 102 and the second externally reflected portion 107 and the strength of the incident t-wave 101.

### EMI Shields

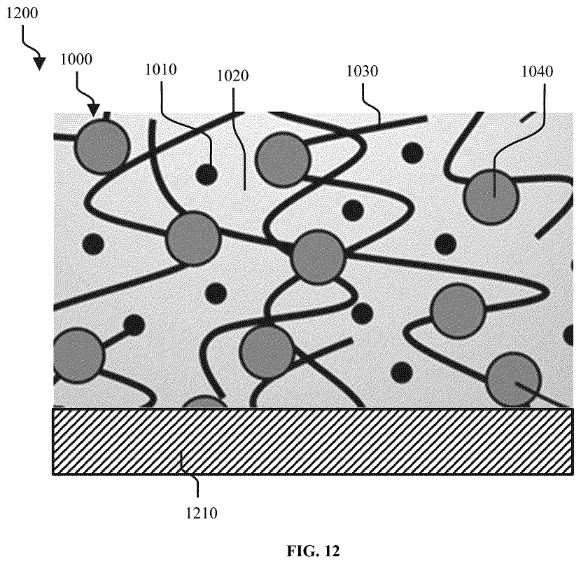

Provided herein, per FIG. 12, is an EMI shield 1200 comprising a substrate 1020 and an EMI shielding coating 1000 comprising a conductive additive 1040 and a binder 1020 deposited on the substrate. In some embodiments, the conductive additive 1040 and the binder 1020 are mixed together to form a coating 1000. In some embodiments, the coating 1000 is easily applied to a variety of substrates for a variety of applications. In some embodiments, the EMI shield 1200 comprises a stack of a plurality of EMI shields 1200. In some embodiments, the EMI shield 1200 further comprises a scratch resistant coating, an impact resistant coating, or any combination thereof.

In some embodiments, the EMI shield 1200 is flexible. In some embodiments, the EMI shield 1200 is rigid. In some embodiments, the EMI shield 1200 is flat. In some embodiments, the EMI shield 1200 is curved. In some embodiments, the EMI shield 1200 is formed into a single surface. In some embodiments, the EMI shield 1200 is formed into a plurality of surfaces.

In some embodiments, the EMI shielding coating 1000 further comprises a thinner 1010. In some embodiments, the thinner 1010 comprises acetone, 4-chloro-alpha, alpha, or alpha-trifluorotoluene. In some embodiments, the EMI shielding coating 1000 further comprises a carbon-based additive 1030. In some embodiments, the carbon-based additive 1030 comprises graphite, graphene, reduced graphene, carbon black, cabot carbon, a carbon nanotube, a functionalized carbon nanotube, or any combination thereof. In some embodiments, the carbon-based additive 1030 enhances the hardness, tensile strength, flexibility, or any combination thereof of the binder 1020. In some embodiments, the carbon-based additive 1030 enhances the conductivity of the EMI shielding coating 1000. These enhanced properties are particularly pronounced in the case of a graphene carbon-based additive.

In some embodiments, the EMI shielding coating 1000 further comprises a viscosity modifier. In some embodiments, the viscosity modifier comprises Acetone, N-Methyl-2-pyrrolidone (NMP), Ethanol, Xylene, Petroleum, N-butyl acetate, Heptan-2-one, 4-isocyanatosulphonyltoluene, 2-Methoxy-1-methylethyl acetate, or combinations thereof.

In some embodiments, the EMI shielding coating 1000 has a thickness of about 10 um to about 1,000 um. In some embodiments, the EMI shielding coating 1000 has a thickness of at least about 10 um, 25 um, 50 um, 100 um, 200 um, 300 um, 400 um, 500 um, 600 um, 700 um, 800 um, or 900 um, including increments therein. In some embodiments, the EMI shielding coating 1000 has a thickness of at most about 25 um, 50 um, 100 um, 150 um, 200 um, 300 um, 400 um, 500 um, 600 um, 700 um, 800 um, 900 um, or 1,000 um, including increments therein.

In some embodiments, the substrate comprises a plastic, a metal, a glass, a fabric, or any combination thereof. In some embodiments, the metal comprises copper, aluminum, steel, stainless steel, beryllium, bismuth, chromium, cobalt, gallium, gold, indium, iron, lead, magnesium, nickel, silver, titanium, tin, zinc, or any combination thereof. In some embodiments, the plastic comprises a thermoplastic. In some embodiments, the thermoplastic comprises polyethylene terephthalate, polyglycolic acid, polylactic acid, polycaprolactone, polyhydroxyalkanoate, polyhydroxybutyrate, polyethylene adipate, polybutylene succinate, poly(3-hydroxybutyrate-co-3-hydroxyvalerate), polybutylene terephthalate, polytrimethylene terephthalate, polyethylene naphthalate, or any combination thereof. In some embodiments, the EMI shield 1200 does not comprise a substrate 1020. In some embodiments, the substrate is planar. In some embodiments, the substrate 1020 is curved. In some embodiments, the substrate 1020 is rigid. In some embodiments, the substrate 1020 is flexible. In some embodiments, the substrate comprises a single surface. In some embodiments, the substrate 1020 comprises two or more surfaces. In some embodiments, the substrate 1020 is a container for an electrical device.

In some embodiments, the metal-based conductive additive 1040 is a metallic nanomaterial comprising nickel, copper, silver, nickel, zinc, aluminum, tin, or gold. In some embodiments, the metallic nanomaterial comprises a first metal forming a metallic core and a second metal forming a coating 1000 around the metallic core. In some embodiments, the first metal comprises aluminum, nickel, copper, or iron, and the second metal comprises silver. In some embodiments, the metallic nanomaterial comprises a morphology comprising nanoparticles, nanorods, nanowires, nanoflowers, nanoflakes, nanofibers, nanoplatelets, nanoribbons, nanocubes, bipyramids, nanodiscs, nanoplates, nanodendrites, nanoleaves, nanospheres, quantum spheres, quantum dots, nanosprings, nanosheets, porous nanosheets, nanomesh, or any combination thereof. In some embodiments, binder 1020 comprises an alkyd, an acrylic, a vinyl-acrylic, vinyl acetate/ethylene (VAE), polyurethane, polyethylene, polyester, styrene, styrene acrylic, melamine, a silane, a siloxane, or any combination thereof. In some embodiments, the metal-based conductive additive 1040 has a width, length or both of about 0.3 μm to about 10 μm. In some embodiments, the metal-based conductive additive 1040 has a width, length or both of at most about 10 μm.

In some embodiments, the EMI shielding coating 1000 comprising the metal-based conductive additive 1040 and the binder 1020 has from 5% w/w to 85% w/w of the metal-based conductive additive 1040. In some embodiments, the EMI shielding coating 1000 comprising the metal-based conductive additive 1040 and the binder 1020 has of at least about 5%, 10%, 20%, 30%, 40%, 50%, 60%, or 70%, w/w of the metal-based conductive additive 1040, including increments therein. In some embodiments, the EMI shielding coating 1000 comprising the metal-based conductive additive 1040 and the binder 1020 has of at most about 10%, 20%, 30%, 40%, 50%, 60%, 70%, or 80% w/w of the metal-based conductive additive 1040, including increments therein.

In some embodiments, the EMI shielding coating 1000 comprising the metal-based conductive additive 1040 and the binder 1020 has from 20% w/w to 95% w/w of the binder 1020. In some embodiments, the EMI shielding coating 1000 comprising the metal-based conductive additive 1040 and the binder 1020 has at least about 20%, 30%, 40%, 50%, 60%, 70%, or 80% w/w of the binder 1020, including increments therein. In some embodiments, the EMI shielding coating 1000 comprising the metal-based conductive additive 1040 and the binder 1020 has at most about 30%, 40%, 50%, 60%, 70%, 80%, or 95% w/w of the binder 1020, including increments therein. In some embodiments, the concentrations of the conductive additive 1040 in the EMI shielding coating 1000 enables the high thermal conductivity, electrical conductivity, heat dissipation, and EMI shielding of the EMI shields 1200 produced therefrom.

In some embodiments, the thinner 1010 constitutes 5% w/w to about 90% w/w of the EMI shielding coating 1000 immediately following deposition on the substrate. In some embodiments, the thinner 1010 constitutes at least about 5%, 10%, 20%, 30%, 40%, 50%, 60%, 70%, or 80% w/w of the EMI shielding coating 1000 immediately following deposition on the substrate. In some embodiments, the thinner 1010 constitutes at most about 10%, 20%, 30%, 40%, 50%, 60%, 70%, 80%, or 90% w/w of the coating EMI shielding 1000 immediately following deposition on the substrate. In some embodiments, the concentrations of the thinner 1010 in the EMI shielding coating 1000 enables the easy preparation and application of the EMI shielding materials herein at various thicknesses and sizes on a variety of substrates to achieve the desired shielding properties of the EMI shields 1200 produced therefrom.

In some embodiments, the carbon-based additive 1030 constitutes from 0.01% w/w to 5% w/w of the EMI shielding coating 1000. In some embodiments, the carbon-based additive 1030 constitutes at least about 0.01%, 0.05%, 0.1%, 0.5%, 1%, 2%, 3%, or 4% w/w of the coating 1000, including increments therein. In some embodiments, the carbon-based additive 1030 constitutes at most about 0.05%, 0.1%, 0.5%, 1%, 2%, 3%, 4%, or 5% w/w of the EMI shielding coating 1000, including increments therein. In some embodiments, the concentrations of the carbon-based additive 1030 in the EMI shielding coating 1000 enables the high thermal conductivity, electrical conductivity, heat dissipation, and EMI shielding of the EMI shields 1200 produced therefrom.

In some embodiments, at least one of the graphene and the graphene oxide has a specific surface area of greater than 1,000 m²/g, 1,250 m²/g, 1,500 m²/g, 1,750 m²/g, 2,000 m²/g, or more. In some embodiments, at least one of the graphene and the graphene oxide has a conductivity of about 1,000 S/m to about 4,000 S/m. In some embodiments, at least one of the graphene and the graphene oxide has a conductivity of at least about 1,000 S/m, 1,500 S/m, 2,000 S/m, 2,500 S/m, 3,000 S/m, 3,500 S/m, or about 4,000 S/m, including increments therein. In some embodiments, the carbon nanotube has an electrical conductivity of greater than about 100 S/m, 110 S/m, 120 S/m, 130 S/m, 140 S/m, 150 S/m, 160 S/m, 170 S/m, 180 S/m, or 200 S/m, including increments therein. In some embodiments, the graphene oxide forms a 3-dimensional network of interconnected carbon sheets, whose high surface area enables the high thermal conductivity, electrical conductivity, heat dissipation, and EMI shielding of the EMI shields 1200 produced therefrom.

In some embodiments, the carbon-based additive 1030 has a mean particle size of about 2 um to about 30 um. In some embodiments, the carbon-based additive 1030 has a mean particle size of at least about 2 um, 5 um, 10 um, 15 um, 20 um, or about 25 um, including increments therein. In some embodiments, the carbon-based additive 1030 has a mean particle size of at most about 5 um, 10 um, 15 um, 20 um, about 25 um, or about 30 um, including increments therein. In some embodiments, the carbon-based additive 1030 has a specific surface area of about 2 m²/g to about 16 m²/g. In some embodiments, the carbon-based additive 1030 has a specific surface area of least about 2 m²/g, 4 m²/g, 6 m²/g, 8 m²/g, 10 m²/g, 12 m²/g, or 14 m²/g, including increments therein. In some embodiments, the particle size and surface area of the carbon-based additive 1030 enables the high thermal conductivity, electrical conductivity, heat dissipation, and EMI shielding of the EMI shields 1200 produced therefrom.

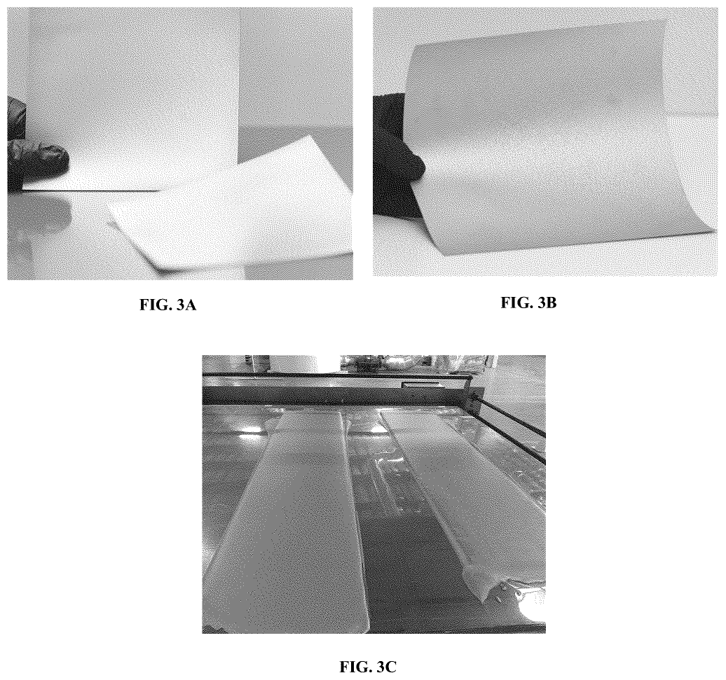

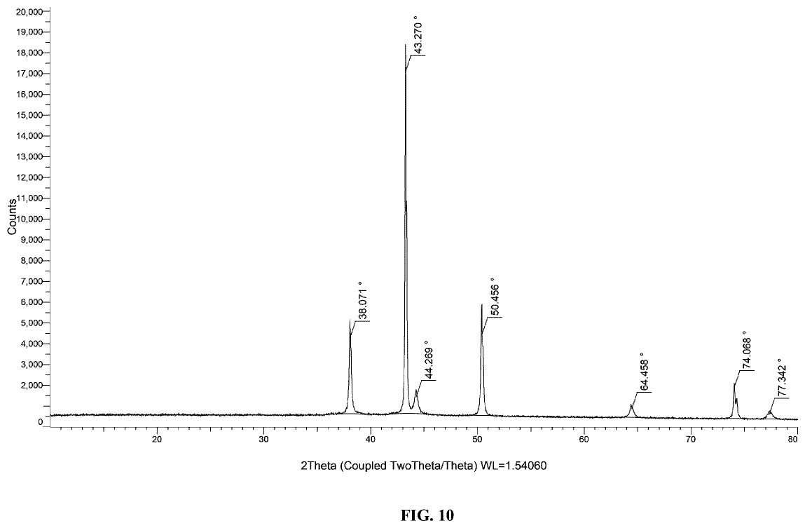

FIGS. 3A-3C show images of first, second, and third exemplary EMI shields, respectively. FIG. 10 shows an XRD (X-Ray Diffraction) graph for an exemplary metal-based conductive additive.

### EMI Shielding Coatings

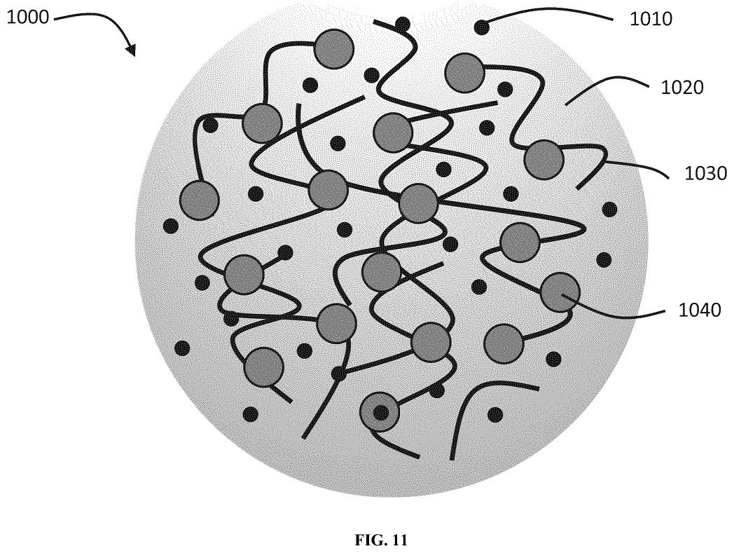

Another aspect provided herein, per FIG. 11, is an EMI shielding coating 1000 comprising: a metal-based conductive additive 1040; a binder 1020; and a solvent incorporated with the metal-based conductive additive 1040 and binder 1020 to form the EMI shielding coating 1000.

In some embodiments, the EMI shielding coating 1000 comprises a clearcoat coating and an activator coating. In some embodiments, mixing the clearcoat coating and the activator coating causes the EMI shielding coating 1000 to cure. In some embodiments, the EMI shielding coating 1000 is configured for application to a substrate by spraying. In some embodiments, the EMI shielding coating 1000 is configured for application to a substrate by air spraying. In some embodiments, the ability of the EMI shielding coating 1000 to be air sprayed onto a substrate enables its application to substrates of various shapes and materials. In some embodiments, the ability of the EMI shielding coating 1000 to be air sprayed onto a substrate enables its application to substrates with greater thickness uniformity.

In some embodiments, the viscosity of the EMI shielding coating 1000 enables its application to a substrate by air spraying. In some embodiments, the EMI shielding coating 1000 has a viscosity of about 25 cP to about 8,000 cP. In some embodiments, the EMI shielding coating 1000 has a viscosity of about 25 cP to about 50 cP, about 25 cP to about 100 cP, about cP to about 250 cP, about 25 cP to about 500 cP, about 25 cP to about 750 cP, about 25 cP to about 1,000 cP, about 25 cP to about 2,000 cP, about 25 cP to about 4,000 cP, about 25 cP to about 6,000 cP, about 25 cP to about 8,000 cP, about 50 cP to about 100 cP, about 50 cP to about 250 cP, about 50 cP to about 500 cP, about 50 cP to about 750 cP, about 50 cP to about 1,000 cP, about 50 cP to about 2,000 cP, about 50 cP to about 4,000 cP, about 50 cP to about 6,000 cP, about 50 cP to about 8,000 cP, about 100 cP to about 250 cP, about 100 cP to about 500 cP, about 100 cP to about 750 cP, about 100 cP to about 1,000 cP, about 100 cP to about 2,000 cP, about 100 cP to about 4,000 cP, about 100 cP to about 6,000 cP, about 100 cP to about 8,000 cP, about 250 cP to about 500 cP, about 250 cP to about 750 cP, about 250 cP to about 1,000 cP, about 250 cP to about 2,000 cP, about 250 cP to about 4,000 cP, about 250 cP to about 6,000 cP, about 250 cP to about 8,000 cP, about 500 cP to about 750 cP, about 500 cP to about 1,000 cP, about 500 cP to about 2,000 cP, about 500 cP to about 4,000 cP, about 500 cP to about 6,000 cP, about 500 cP to about 8,000 cP, about 750 cP to about 1,000 cP, about 750 cP to about 2,000 cP, about 750 cP to about 4,000 cP, about 750 cP to about 6,000 cP, about 750 cP to about 8,000 cP, about 1,000 cP to about 2,000 cP, about 1,000 cP to about 4,000 cP, about 1,000 cP to about 6,000 cP, about 1,000 cP to about 8,000 cP, about 2,000 cP to about 4,000 cP, about 2,000 cP to about 6,000 cP, about 2,000 cP to about 8,000 cP, about 4,000 cP to about 6,000 cP, about 4,000 cP to about 8,000 cP, or about 6,000 cP to about 8,000 cP, including increments therein. In some embodiments, the EMI shielding coating 1000 has a viscosity of about 25 cP, about 50 cP, about 100 cP, about 250 cP, about 500 cP, about 750 cP, about 1,000 cP, about 2,000 cP, about 4,000 cP, about 6,000 cP, or about 8,000 cP. In some embodiments, the EMI shielding coating 1000 has a viscosity of at least about 25 cP, about 50 cP, about 100 cP, about 250 cP, about 500 cP, about 750 cP, about 1,000 cP, about 2,000 cP, about 4,000 cP, or about 6,000 cP. In some embodiments, the EMI shielding coating 1000 has a viscosity of at most about 50 cP, about 100 cP, about 250 cP, about 500 cP, about 750 cP, about 1,000 cP, about 2,000 cP, about 4,000 cP, about 6,000 cP, or about 8,000 cP.

In some embodiments, the viscosity of the clear coating and the activator coating enables its application to a substrate by air spraying. In some embodiments, the clear coating and the activator coating have a viscosity of about 25 cP to about 8,000 cP. In some embodiments, the clear coating and the activator coating have a viscosity of about 25 cP to about 50 cP, about 25 cP to about 100 cP, about 25 cP to about 250 cP, about 25 cP to about 500 cP, about 25 cP to about 750 cP, about 25 cP to about 1,000 cP, about 25 cP to about 2,000 cP, about 25 cP to about 4,000 cP, about 25 cP to about 6,000 cP, about 25 cP to about 8,000 cP, about 50 cP to about 100 cP, about 50 cP to about 250 cP, about 50 cP to about 500 cP, about 50 cP to about 750 cP, about 50 cP to about 1,000 cP, about 50 cP to about 2,000 cP, about 50 cP to about 4,000 cP, about 50 cP to about 6,000 cP, about 50 cP to about 8,000 cP, about 100 cP to about 250 cP, about 100 cP to about 500 cP, about 100 cP to about 750 cP, about 100 cP to about 1,000 cP, about 100 cP to about 2,000 cP, about 100 cP to about 4,000 cP, about 100 cP to about 6,000 cP, about 100 cP to about 8,000 cP, about 250 cP to about 500 cP, about 250 cP to about 750 cP, about 250 cP to about 1,000 cP, about 250 cP to about 2,000 cP, about 250 cP to about 4,000 cP, about 250 cP to about 6,000 cP, about 250 cP to about 8,000 cP, about 500 cP to about 750 cP, about 500 cP to about 1,000 cP, about 500 cP to about 2,000 cP, about 500 cP to about 4,000 cP, about 500 cP to about 6,000 cP, about 500 cP to about 8,000 cP, about 750 cP to about 1,000 cP, about 750 cP to about 2,000 cP, about 750 cP to about 4,000 cP, about 750 cP to about 6,000 cP, about 750 cP to about 8,000 cP, about 1,000 cP to about 2,000 cP, about 1,000 cP to about 4,000 cP, about 1,000 cP to about 6,000 cP, about 1,000 cP to about 8,000 cP, about 2,000 cP to about 4,000 cP, about 2,000 cP to about 6,000 cP, about 2,000 cP to about 8,000 cP, about 4,000 cP to about 6,000 cP, about 4,000 cP to about 8,000 cP, or about 6,000 cP to about 8,000 cP, including increments therein. In some embodiments, the clear coating and the activator coating have a viscosity of about 25 cP, about 50 cP, about 100 cP, about 250 cP, about 500 cP, about 750 cP, about 1,000 cP, about 2,000 cP, about 4,000 cP, about 6,000 cP, or about 8,000 cP. In some embodiments, the clear coating and the activator coating have a viscosity of at least about 25 cP, about 50 cP, about 100 cP, about 250 cP, about 500 cP, about 750 cP, about 1,000 cP, about 2,000 cP, about 4,000 cP, or about 6,000 cP. In some embodiments, the clear coating and the activator coating have a viscosity of at most about 50 cP, about 100 cP, about 250 cP, about 500 cP, about 750 cP, about 1,000 cP, about 2,000 cP, about 4,000 cP, about 6,000 cP, or about 8,000 cP.

In some embodiments, the metal-based conductive additive 1040 is a metallic nanomaterial comprising nickel, copper, silver, nickel, zinc, aluminum, tin, or gold. In some embodiments, the metallic nanomaterial comprises a first metal forming a metallic core and a second metal forming a coating around the metallic core. In some embodiments, the first metal comprises aluminum, nickel, copper, or iron, and the second metal comprises silver. In some embodiments, the metallic nanomaterial comprises a morphology comprising nanoparticles, nanorods, nanowires, nanoflowers, nanoflakes, nanofibers, nanoplatelets, nanoribbons, nanocubes, bipyramids, nanodiscs, nanoplates, nanodendrites, nanoleaves, nanospheres, quantum spheres, quantum dots, nanosprings, nanosheets, porous nanosheets, nanomesh, or any combination thereof. In some embodiments, binder 1020 comprises an alkyd, an acrylic, a vinyl-acrylic, vinyl acetate/ethylene (VAE), polyurethane, polyethylene, polyester, styrene, styrene acrylic, melamine, a silane, a siloxane, or any combination thereof.

In some embodiments, the EMI shielding coating 1000 comprising the metal-based conductive additive 1040 and the binder 1020 has from 5% w/w to 85% w/w of the metal-based conductive additive 1040. In some embodiments, the EMI shielding coating 1000 comprising the metal-based conductive additive 1040 and the binder 1020 has at least about 5%, 10%, 20%, 30%, 40%, 50%, 60%, or 70%, of the metal-based conductive additive 1040, including increments therein. In some embodiments, the EMI shielding coating 1000 comprising the metal-based conductive additive 1040 and the binder 1020 has at most about 10%, 20%, 30%, 40%, 50%, 60%, 70%, or 80% of the metal-based conductive additive 1040, including increments therein. In some embodiments, the percentage of the metal-based conductive additive 1040 in the EMI shielding coating 1000 enables its high conductivity, low sheet resistance, and high shielding effectiveness, while maintaining a viscosity that enables its application to a substrate by air spraying.

In some embodiments, the EMI shielding coating 1000 comprising the metal-based conductive additive 1040 and the binder 1020 has from 20% w/w to 95% w/w of the binder 1020. In some embodiments, the EMI shielding coating 1000 comprising the metal-based conductive additive 1040 and the binder 1020 has at least about 20%, 30%, 40%, 50%, 60%, 70%, or 80% w/w of the binder 1020. In some embodiments, the EMI shielding coating 1000 comprising the metal-based conductive additive 1040 and the binder 1020 has at most about 30%, 40%, 50%, 60%, 70%, 80%, or 95% w/w of the binder 1020. In some embodiments, the percentage of the binder 1020 in the EMI shielding coating 1000 enables its high conductivity, low sheet resistance, and high shielding effectiveness, while maintaining a viscosity that enables its application to a substrate by air spraying.

In some embodiments, the EMI shielding coating 1000 further comprises a coating thinner 1010. In some embodiments, the coating thinner 1010 comprises acetone, 4-chloro-alpha, alpha, or alpha-trifluorotoluene. In some embodiments, the coating thinner 1010 constitutes 5% w/w to about 90% w/w of the EMI shielding coating 1000 immediately following deposition on the substrate. In some embodiments, the coating thinner 1010 constitutes at least about 5%, 10%, 20%, 30%, 40%, 50%, 60%, 70%, or 80% w/w of the EMI shielding coating 1000 immediately following deposition on the substrate, including increments therein. In some embodiments, the coating thinner 1010 constitutes at most about 10%, 20%, 30%, 40%, 50%, 60%, 70%, 80%, or 90% w/w of the EMI shielding coating 1000 immediately following deposition on the substrate, including increments therein. In some embodiments, the percentage of the coating thinner 1010 in the EMI shielding coating 1000 enables its high conductivity, low sheet resistance, and high shielding effectiveness, while maintaining a viscosity that enables its application to a substrate by air spraying.

In some embodiments, the EMI shielding coating 1000 further comprises a viscosity modifier. In some embodiments, the viscosity modifier comprises Acetone, N-Methyl-2-pyrrolidone (NMP), Ethanol, Xylene, Petroleum, N-butyl acetate, Heptan-2-one, 4-isocyanatosulphonyltoluene, 2-Methoxy-1-methylethyl acetate, or combinations thereof.

In some embodiments, the EMI shielding coating further comprises a carbon-based additive 1030. In some embodiments, the carbon-based additive 1030 comprises graphite, graphene, reduced graphene, carbon black, cabot carbon, a carbon nanotube, a functionalized carbon nanotube, or any combination thereof. In some embodiments, the carbon-based additive 1030 constitutes from 0.01% w/w to 5% w/w of the EMI shielding coating 1000. In some embodiments, the carbon-based additive 1030 constitutes at least about 0.01%, 0.05%, 0.1%, 1%, 2%, 3%, or 4%, of the EMI shielding coating 1000, including increments therein. In some embodiments, the carbon-based additive 1030 constitutes at most about 0.05%, 0.1%, 1%, 2%, 3%, 4%, or 5% of the EMI shielding coating 1000, including increments therein. In some embodiments, the percentage of the carbon-based additive 1030 in the EMI shielding coating 1000 enables its high conductivity, low sheet resistance, and high shielding effectiveness, while maintaining a viscosity that enables its application to a substrate by air spraying.

In some embodiments, at least one of the graphene and the graphene oxide has a specific surface area of greater than 1,000 m²/g, 1,250 m²/g, 1,500 m²/g, 1,750 m²/g, 2,000 m²/g, or more. In some embodiments, at least one of the graphene and the graphene oxide has a conductivity of about 1,000 S/m to about 4,000 S/m. In some embodiments, at least one of the graphene and the graphene oxide has a conductivity of at least about 1,000 S/m, 1,500 S/m, 2,000 S/m, 2,500 S/m, 3,000 S/m, 3,500 S/m, or about 4,000 S/m, including increments therein. In some embodiments, the carbon nanotube has an electrical conductivity of greater than about 100 S/m, 110 S/m, 120 S/m, 130 S/m, 140 S/m, 150 S/m, 160 S/m, 170 S/m, 180 S/m, or 200 S/m, including increments therein. In some embodiments, the carbon-based additive 1030 has a specific surface area of about 2 m²/g to about 16 m²/g. In some embodiments, the carbon-based additive 1030 has a specific surface area of least about 2 m²/g, 4 m²/g, 6 m²/g, 8 m²/g, 10 m²/g, 12 m²/g, or 14 m²/g, including increments therein. In some embodiments, the specific surface area, conductivity, or both of the carbon-based additives 1030 herein enables the high conductivity, low sheet resistance, and high shielding effectiveness, of the EMI shielding coating 1000

In some embodiments, the carbon-based additive 1030 has a mean particle size of about 2 um to about 30 um. In some embodiments, the carbon-based additive 1030 has a mean particle size of at least about 2 um, 5 um, 10 um, 15 um, 20 um, or about 25 um, including increments therein. In some embodiments, the carbon-based additive 1030 has a mean particle size of at most about 5 um, 10 um, 15 um, 20 um, about 25 um, or about 30 um, including increments therein. In some embodiments, the mean particle size of the carbon-based additive 1030, its high conductivity, low sheet resistance, and high shielding effectiveness, provide improved electronic properties while maintaining a viscosity that enables its application to a substrate by air spraying. In some embodiments, the mean particle size of the carbon-based additive 1030 prevents particle clogging during air spraying.

### Methods of Forming an EMI Shield

Another aspect provided herein are methods of forming an EMI shield. In some embodiments, the method comprises: obtaining a coating comprising a metal-based conductive additive, a binder, and a solvent; applying the coating onto a substrate; and drying the coating on the substrate to form an EMI shielding coating.

In some embodiments, obtaining the coating comprises mixing a clearcoat coating and an activator coating, wherein the clearcoat coating and the activator coating both comprise the metal-based conductive additive, the binder, and the solvent, wherein the activator coating further comprises an activator for curing the coating. In some embodiments, mixing the clearcoat coating and the activator coating causes the EMI shielding coating to cure.

In some embodiments, the method comprises: forming a coating comprising a metal-based conductive additive, a binder, and a solvent; depositing the coating on a substrate; and drying the coating on the substrate to form an EMI shielding coating.

In some embodiments, the forming of the coating comprises: mixing the coating; breaking down agglomerates in the coating; removing air bubbles from the coating; or any combination thereof. In some embodiments, the mixing is performed by an acoustic mixer. In some embodiments, the breaking down of the agglomerates in the coating is performed by a high shear mixer. In some embodiments, the removing of the air bubbles from the coating is performed by a vacuum mixer.

In some embodiments, the viscosity of the EMI shielding coating enables its application to a substrate by air spraying. In some embodiments, at least one of the breaking down of the agglomerates in the coating and the removing of the air bubbles from the coating is performed until the coating has a viscosity of about 25 cP to about 8,000 cP. In some embodiments, at least one of the breaking down of the agglomerates in the coating and the removing of the air bubbles from the coating is performed until the coating has a viscosity of about 25 cP to about 50 cP, about 25 cP to about 100 cP, about 25 cP to about 250 cP, about 25 cP to about 500 cP, about 25 cP to about 750 cP, about 25 cP to about 1,000 cP, about 25 cP to about 2,000 cP, about 25 cP to about 4,000 cP, about 25 cP to about 6,000 cP, about 25 cP to about 8,000 cP, about 50 cP to about 100 cP, about 50 cP to about 250 cP, about 50 cP to about 500 cP, about 50 cP to about 750 cP, about 50 cP to about 1,000 cP, about 50 cP to about 2,000 cP, about 50 cP to about 4,000 cP, about 50 cP to about 6,000 cP, about 50 cP to about 8,000 cP, about 100 cP to about 250 cP, about 100 cP to about 500 cP, about 100 cP to about 750 cP, about 100 cP to about 1,000 cP, about 100 cP to about 2,000 cP, about 100 cP to about 4,000 cP, about 100 cP to about 6,000 cP, about 100 cP to about 8,000 cP, about 250 cP to about 500 cP, about 250 cP to about 750 cP, about 250 cP to about 1,000 cP, about 250 cP to about 2,000 cP, about 250 cP to about 4,000 cP, about 250 cP to about 6,000 cP, about 250 cP to about 8,000 cP, about 500 cP to about 750 cP, about 500 cP to about 1,000 cP, about 500 cP to about 2,000 cP, about 500 cP to about 4,000 cP, about 500 cP to about 6,000 cP, about 500 cP to about 8,000 cP, about 750 cP to about 1,000 cP, about 750 cP to about 2,000 cP, about 750 cP to about 4,000 cP, about 750 cP to about 6,000 cP, about 750 cP to about 8,000 cP, about 1,000 cP to about 2,000 cP, about 1,000 cP to about 4,000 cP, about 1,000 cP to about 6,000 cP, about 1,000 cP to about 8,000 cP, about 2,000 cP to about 4,000 cP, about 2,000 cP to about 6,000 cP, about 2,000 cP to about 8,000 cP, about 4,000 cP to about 6,000 cP, about 4,000 cP to about 8,000 cP, or about 6,000 cP to about 8,000 cP, including increments therein. In some embodiments, at least one of the breaking down of the agglomerates in the coating and the removing of the air bubbles from the coating is performed until the coating has a viscosity of about 25 cP, about 50 cP, about 100 cP, about 250 cP, about 500 cP, about 750 cP, about 1,000 cP, about 2,000 cP, about 4,000 cP, about 6,000 cP, or about 8,000 cP. In some embodiments, at least one of the breaking down of the agglomerates in the coating and the removing of the air bubbles from the coating is performed until the coating has a viscosity of at least about 25 cP, about 50 cP, about 100 cP, about 250 cP, about 500 cP, about 750 cP, about 1,000 cP, about 2,000 cP, about 4,000 cP, or about 6,000 cP. In some embodiments, at least one of the breaking down of the agglomerates in the coating and the removing of the air bubbles from the coating is performed until the coating has a viscosity of at most about 50 cP, about 100 cP, about 250 cP, about 500 cP, about 750 cP, about 1,000 cP, about 2,000 cP, about 4,000 cP, about 6,000 cP, or about 8,000 cP. In some embodiments, the coating has a viscosity of about 25 cP to about 8,000 cP. In some embodiments, at least one of the breaking down of the agglomerates in the coating and the removing of the air bubbles from the coating enables the formation of the EMI shielding coating that can be applied to a substrate by a variety of methods and/or devices.

In some embodiments, a set thickness of the coating is deposited on the substrate. In some embodiments, a set thickness of the coating is painted on the substrate. In some embodiments, depositing the coating on a substrate comprises depositing the coating on the substrate with a coating machine. In some embodiments, the coating machine is a slot die coating machine, a table-top coating machine, or both. In some embodiments, the coating is applied onto the substrate by spraying. In some embodiments, the coating is applied onto the substrate by air spraying. In some embodiments, the substrate and the coating are oppositely charged to enable uniform coating of the substrate and to reduce the volume of lost paint.

In some embodiments, the method further comprises calendaring the EMI shield. In some embodiments, calendaring is performed by a roll to roll calendaring machine. In some embodiments, drying the coating on the substrate comprises drying the coating on the substrate, curing the coating on the substrate, or both. In some embodiments, drying the coating on the substrate is performed at a temperature of about 20° C. to about 120° C. In some embodiments, drying the coating on the substrate is performed at room temperature. In some embodiments, drying the coating on the substrate is performed for a time of about 15 minutes to about 60 minutes. In some embodiments, the drying is performed by a heat lamp. In some embodiments, drying the coating on the substrate is performed for a time of about 0.5 days to about 21 days. In some embodiments, curing the EMI coating on the substrate is performed at a temperature of about 120° F. to about 160° F. In some embodiments, curing the EMI coating on the substrate is performed for a time period of about 15 minutes to about 30 minutes.

In some embodiments, the metal-based conductive additive is a metallic nanomaterial comprising nickel, copper, silver, nickel, zinc, aluminum, tin, or gold. In some embodiments, the metallic nanomaterial comprises a first metal forming a metallic core and a second metal forming a coating around the metallic core. In some embodiments, the first metal comprises aluminum, nickel, copper, or iron, and the second metal comprises silver. In some embodiments, the metallic nanomaterial comprises a morphology comprising nanoparticles, nanorods, nanowires, nanoflowers, nanoflakes, nanofibers, nanoplatelets, nanoribbons, nanocubes, bipyramids, nanodiscs, nanoplates, nanodendrites, nanoleaves, nanospheres, quantum spheres, quantum dots, nanosprings, nanosheets, porous nanosheets, nanomesh, or any combination thereof. In some embodiments, binder comprises an alkyd, an acrylic, a vinyl-acrylic, vinyl acetate/ethylene (VAE), polyurethane, polyethylene, polyester, styrene, styrene acrylic, melamine, a silane, a siloxane, or any combination thereof.

In some embodiments, the EMI shielding coating comprising the metal-based conductive additive and the binder has from 5% w/w to 85% w/w of the metal-based conductive additive. In some embodiments, the EMI shielding coating comprising the metal-based conductive additive and the binder has at least about 5%, 10%, 20%, 30%, 40%, 50%, 60%, or 70%, of the metal-based conductive additive, including increments therein. In some embodiments, the EMI shielding coating comprising the metal-based conductive additive and the binder has at most about 10%, 20%, 30%, 40%, 50%, 60%, 70%, or 80% of the metal-based conductive additive, including increments therein. In some embodiments, the percentage of the metal-based conductive additive in the EMI shielding coating enables its high conductivity, low sheet resistance, and high shielding effectiveness, while maintaining a viscosity that enables its application to a substrate by air spraying.

In some embodiments, the EMI shielding coating comprising the metal-based conductive additive and the binder has from 20% w/w to 95% w/w of the binder. In some embodiments, the EMI shielding coating comprising the metal-based conductive additive and the binder has at least about 20%, 30%, 40%, 50%, 60%, 70%, or 80% w/w of the binder. In some embodiments, the EMI shielding coating comprising the metal-based conductive additive and the binder has at most about 30%, 40%, 50%, 60%, 70%, 80%, or 95% w/w of the binder. In some embodiments, the percentage of the binder in the EMI shielding coating enables its high conductivity, low sheet resistance, and high shielding effectiveness, while maintaining a viscosity that enables its application to a substrate by air spraying.

In some embodiments, the EMI shielding coating further comprises a coating thinner. In some embodiments, the coating thinner comprises acetone, 4-chloro-alpha, alpha, or alpha-trifluorotoluene. In some embodiments, the coating thinner constitutes 5% w/w to about 90% w/w of the coating immediately following deposition on the substrate. In some embodiments, the coating thinner constitutes at least about 5%, 10%, 20%, 30%, 40%, 50%, 60%, 70%, or 80% w/w of the coating immediately following deposition on the substrate, including increments therein. In some embodiments, the coating thinner constitutes at most about 10%, 20%, 30%, 40%, 50%, 60%, 70%, 80%, or 90% w/w of the coating immediately following deposition on the substrate, including increments therein. In some embodiments, the percentage of the coating thinner in the EMI shielding coating enables its high conductivity, low sheet resistance, and high shielding effectiveness, while maintaining a viscosity that enables its application to a substrate by air spraying.

In some embodiments, the EMI shielding coating further comprises a viscosity modifier. In some embodiments, the viscosity modifier comprises Acetone, N-Methyl-2-pyrrolidone (NMP), Ethanol, Xylene, Petroleum, N-butyl acetate, Heptan-2-one, 4-isocyanatosulphonyltoluene, 2-Methoxy-1-methylethyl acetate, or combinations thereof.

In some embodiments, the EMI shielding coating further comprises a carbon-based additive. In some embodiments, the carbon-based additive comprises graphite, graphene, reduced graphene, carbon black, cabot carbon, a carbon nanotube, a functionalized carbon nanotube, or any combination thereof. In some embodiments, the carbon-based additive constitutes from 0.01% w/w to 5% w/w of the coating. In some embodiments, the carbon-based additive constitutes at least about 0.01%, 0.05%, 0.1%, 0.5%, 1%, 2%, 3%, or 4%, of the coating, including increments therein. In some embodiments, the carbon-based additive constitutes at most about 0.05%, 0.1%, 0.5%, 1%, 2%, 3%, 4%, or 5% of the coating, including increments therein. In some embodiments, the percentage of the carbon-based additive in the EMI shielding coating enables its high conductivity, low sheet resistance, and high shielding effectiveness, while maintaining a viscosity that enables its application to a substrate by air spraying.

In some embodiments, at least one of the graphene and the graphene oxide has a specific surface area of greater than 1,000 m²/g, 1,250 m²/g, 1,500 m²/g, 1,750 m²/g, 2,000 m²/g, or more. In some embodiments, at least one of the graphene and the graphene oxide has a conductivity of about 1,000 S/m to about 4,000 S/m. In some embodiments, at least one of the graphene and the graphene oxide has a conductivity of at least about 1,000 S/m, 1,500 S/m, 2,000 S/m, 2,500 S/m, 3,000 S/m, 3,500 S/m, or about 4,000 S/m, including increments therein. In some embodiments, the carbon nanotube has an electrical conductivity of greater than about 100 S/m, 110 S/m, 120 S/m, 130 S/m, 140 S/m, 150 S/m, 160 S/m, 170 S/m, 180 S/m, or 200 S/m, including increments therein. In some embodiments, the carbon-based additive has a specific surface area of about 2 m²/g to about 16 m²/g. In some embodiments, the carbon-based additive has a specific surface area of least about 2 m²/g, 4 m²/g, 6 m²/g, 8 m²/g, 10 m²/g, 12 m²/g, or 14 m²/g, including increments therein.

In some embodiments, the carbon-based additive has a mean particle size of about 2 um to about 30 um. In some embodiments, the carbon-based additive has a mean particle size of at least about 2 um, 5 um, 10 um, 15 um, 20 um, or about 25 um, including increments therein. In some embodiments, the carbon-based additive has a mean particle size of at most about 5 um, 10 um, 15 um, 20 um, about 25 um, or about 30 um, including increments therein. In some embodiments, the mean particle size of the carbon-based additive its high conductivity, low sheet resistance, and high shielding effectiveness, while maintaining a viscosity that enables its application to a substrate by air spraying. In some embodiments, the mean particle size of the carbon-based additive its high conductivity, low sheet resistance, and high shielding effectiveness, while preventing particle clogging during air spraying.

### EMI Shield Effectiveness Testing

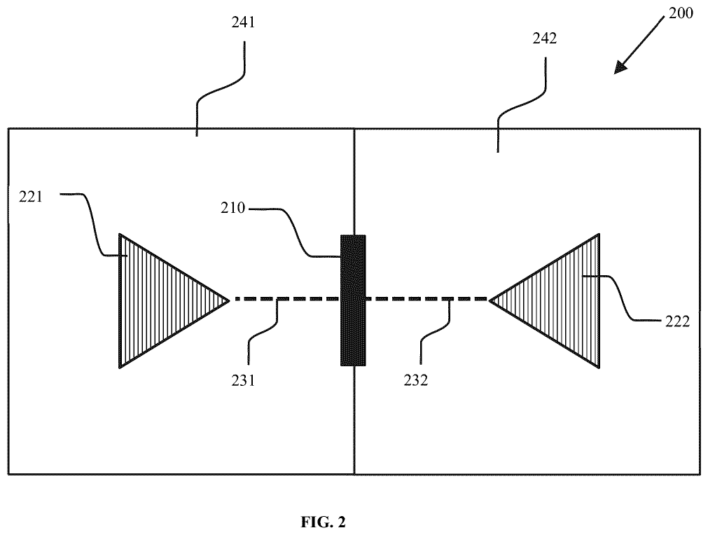

Although various apparatuses or methods known to one of skill in the art can be employed to test the Electromagnetic Interference (EMI) shield effectiveness of a sample 210, FIG. 2 shows a diagram of an EMI shield effectiveness testing apparatus 200. As shown the apparatus 200 comprises a transmitting antenna 221 and a receiving antenna 222 that are separated by the EMI shielding sample 210. Further as shown, the transmitting antenna 221 emits an unattenuated signal 231, whereas the EMI shielding sample 210 blocks all but an attenuated signal 232 from reaching the receiving antenna 222. The shielding effectiveness of the EMI shielding sample 210 can be determined as the difference between the power of the unattenuated signal 231 and the attenuated signal 232.

In some embodiments, per FIG. 2, the transmitting antenna 221 is contained within a first shielded enclosure 241 and the receiving antenna 222 is contained with a second shielded enclosure 242. Alternatively, in some embodiments, only the transmitting antenna 221 is contained within the first shielded enclosure 241, whereas the receiving antenna 222 is not contained with the second shielded enclosure 242. Alternatively, in some embodiments, only the receiving antenna 222 is contained with the second shielded enclosure 242, wherein the transmitting antenna 221 is not contained within the first shielded enclosure 241.

In some embodiments, the transmitting antenna 221 receives the unattenuated signal 231 from a signal generator. In some embodiments, the transmitting antenna 221 receives the unattenuated signal 231 from a power amplifier receiving the unattenuated signal 231 from the signal generator. In some embodiments, the receiving antenna 222 transmits the attenuated signal 232 to a spectrum analyzer, a signal analyzer, or any combination thereof.

In some embodiments, the transmitting antenna 221 and the receiving antenna 222 are aligned such that the unattenuated signal 231 and the attenuated signal 232 are both perpendicular to the EMI shielding sample 210. In some embodiments, the transmitting antenna 221 and the receiving antenna 222 are aligned such that the unattenuated signal 231 and the attenuated signal 232 are emitted at the center of the EMI shielding sample 210. In some embodiments, the transmitting antenna 221 is separated from the EMI shielding sample 210 by about 50 cm. In some embodiments, the receiving antenna 222 is separated from the EMI shielding sample 210 by about 50 cm. In some embodiments, the transmitting antenna 221 and the receiving are separated from each other by about 100 cm.

### EMI Shield Performance

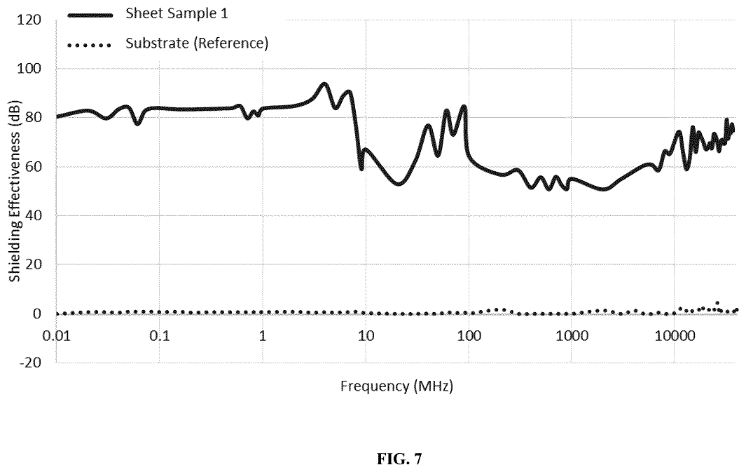

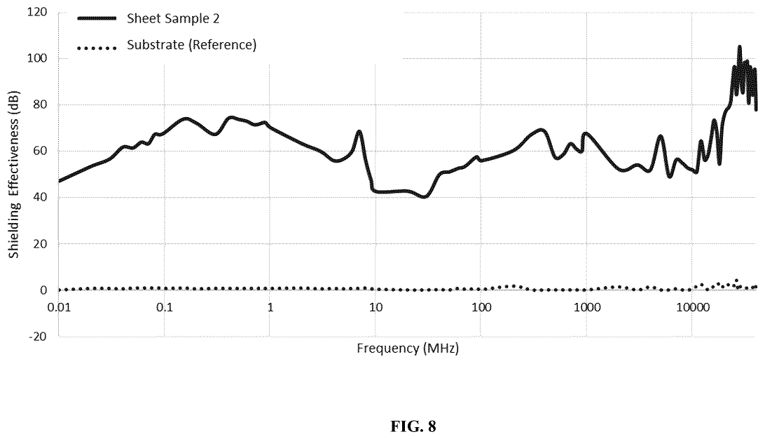

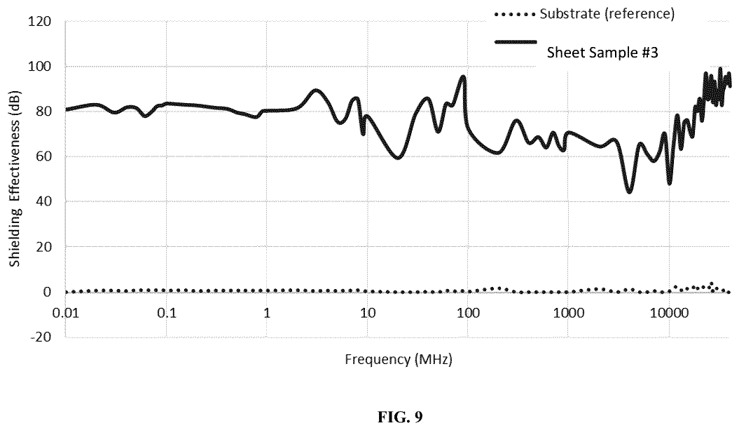

FIGS. 7-9 show shielding effectiveness graphs of first, second, and third exemplary EMI shields, respectively.

In some embodiments the EMI shield has a conductivity of about 10 S/m to about 20,000 S/m. In some embodiments the EMI shield has a conductivity of at least about 10 S/m, 25 S/m, S/m, 100 S/m, 250 S/m, 500 S/m, 1,000 S/m, 2,500 S/m, 5,000 S/m, 10,000 S/m, or 15,000 S/m, including increments therein. In some embodiments the EMI shield has a sheet resistance of about 0.1 ohm/sq to about 1,000 ohm/sq. In some embodiments the EMI shield has a sheet resistance of at most about 0.2 ohm/sq, 0.5 ohm/sq, 1 ohm/sq, 5 ohm/sq, 10 ohm/sq, 50 ohm/sq, 100 ohm/sq, 200 ohm/sq, 300 ohm/sq, 400 ohm/sq, 500 ohm/sq, 600 ohm/sq, 700 ohm/sq, 800 ohm/sq, or 900 ohm/sq, including increments therein. In some embodiments the EMI shield has an operating temperature of at about 0° C. to about 400° C. In some embodiments the EMI shield has an operating temperature of at least about 0° C., 10° C., 25° C., 50° C., 100° C., 150° C., 200° C., 250° C., 300° C., or 400° C.

In some embodiments, the EMI shield has a shielding effectiveness in the frequency range of about 10 kHz to about 40 GHz of about 10 dB to about 130 dB. In some embodiments, the EMI shield has a shielding effectiveness in the frequency range of about 10 kHz to about 40 GHz about 10 dB to about 130 dB with an EMI shielding coating thickness of less than about 150 um. In some embodiments the EMI shield has a shielding effectiveness in the frequency range of about 10 kHz to about 400 kHz of about 20 dB to about 100 dB with an EMI shielding coating thickness of less than about 150 um. In some embodiments the EMI shield has a shielding effectiveness in the frequency range of about 500 kHz to about 30 MHz of about 20 dB to about 100 dB with an EMI shielding coating thickness of less than about 150 um. In some embodiments the EMI shield has a shielding effectiveness in the frequency range of about 40 MHz to about 1 GHz of about 10 dB to about 100 dB with a film thickness of less than about 150 um. In some embodiments the EMI shield has a shielding effectiveness in the frequency range of 2 GHz to 18 GHz of about 30 dB to about 120 dB with a film thickness of less than about 150 um. In some embodiments the EMI shield has a shielding effectiveness in the frequency range of 19 GHz to 40 GHz of about 50 dB to about 130 dB with a film thickness of less than about 150 um.

### EMI Shielding Coating Performance

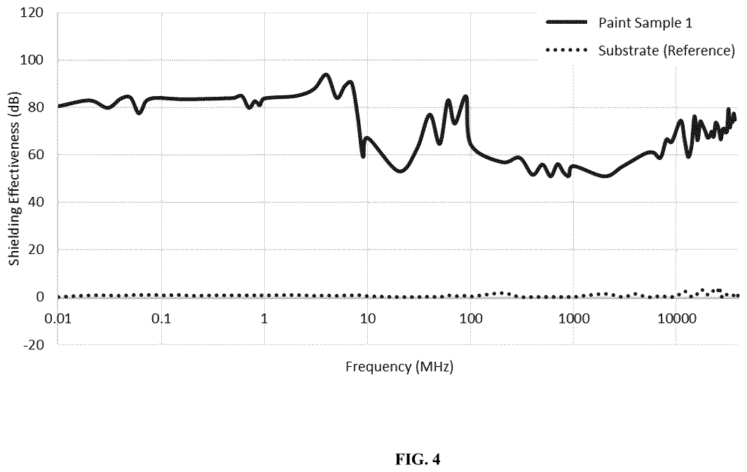

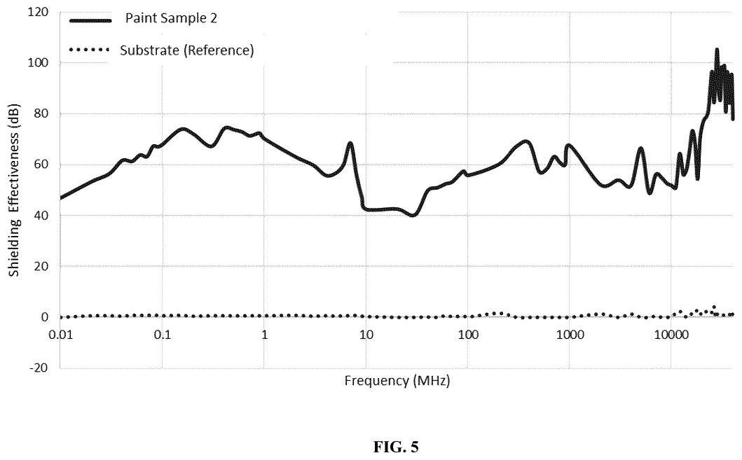

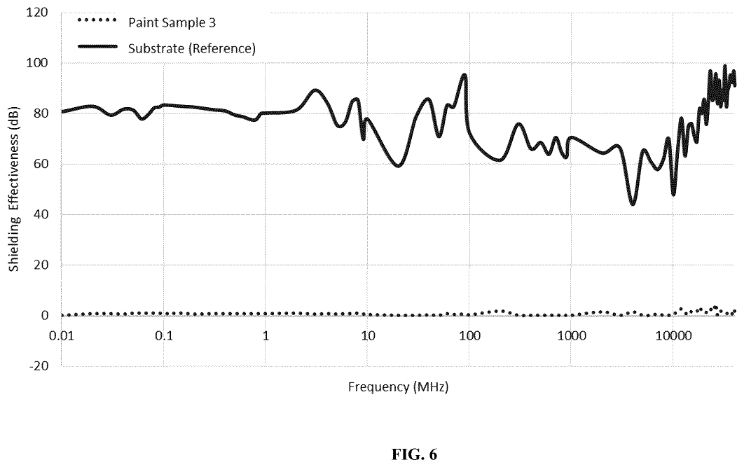

FIGS. 4-6 show shielding effectiveness graphs of first, second, and third exemplary EMI shields, respectively.

In some embodiments the EMI shielding coating when dry has a conductivity of about S/m to about 20,000 S/m. In some embodiments the EMI shielding coating when dry has a conductivity of at least about 10 S/m, 25 S/m, 50 S/m, 100 S/m, 250 S/m, 500 S/m, 1,000 S/m, 2,500 S/m, 5,000 S/m, 10,000 S/m, or 15,000 S/m, including increments therein. In some embodiments the EMI shielding coating when dry has a sheet resistance of about 0.1 ohm/sq to about 1,000 ohm/sq. In some embodiments the EMI shielding coating when dry has a sheet resistance of at most about 0.2 ohm/sq, 0.5 ohm/sq, 1 ohm/sq, 5 ohm/sq, 10 ohm/sq, 50 ohm/sq, 100 ohm/sq, 200 ohm/sq, 300 ohm/sq, 400 ohm/sq, 500 ohm/sq, 600 ohm/sq, 700 ohm/sq, 800 ohm/sq, or 900 ohm/sq, including increments therein. In some embodiments the EMI shielding coating when dry has an operating temperature of at about 0° C. to about 400° C. In some embodiments the EMI shielding coating when dry has an operating temperature of at least about ° C., 10° C., 25° C., 50° C., 100° C., 150° C., 200° C., 250° C., 300° C., or 400° C.

In some embodiments, the EMI shielding coating when dry has a shielding effectiveness in the frequency range of about 10 kHz to about 40 GHz about 10 dB to about 130 dB. In some embodiments, the EMI shielding coating when dry has a shielding effectiveness in the frequency range of about 10 kHz to about 40 GHz about 10 dB to about 130 dB with an EMI shielding coating when drying coating when dry thickness of less than about 150 um. In some embodiments the EMI shielding coating when dry has a shielding effectiveness in the frequency range of about 10 kHz to about 400 kHz of about 20 dB to about 100 dB with an EMI shielding coating when drying coating when dry thickness of less than about 150 um. In some embodiments the EMI shielding coating when dry has a shielding effectiveness in the frequency range of about 500 kHz to about 30 MHz of about 20 dB to about 100 dB with an EMI shielding coating when drying coating when dry thickness of less than about 150 um. In some embodiments the EMI shielding coating when dry has a shielding effectiveness in the frequency range of about 40 MHz to about 1 GHz of about 10 dB to about 100 dB with a film thickness of less than about 150 um. In some embodiments the EMI shielding coating when dry has a shielding effectiveness in the frequency range of 2 GHz to 18 GHz of about 30 dB to about 120 dB with a film thickness of less than about 150 um. In some embodiments the EMI shielding coating when dry has a shielding effectiveness in the frequency range of 19 GHz to 40 GHz of about 50 dB to about 130 dB with a film thickness of less than about 150 um.

### Certain Embodiments of EMI Coatings

First, second, and third EMI coatings were created per Table 1 below.

TABLE 1

| Shielding Sample | First | Second | Third |
|---|---|---|---|
| Metal Based Conductive Additive | — | 5-90 | 5-90 |
| (%) | | | |
| Carbon Based Conductive Additive | — | 0.01-5 | 0.01-5 |
| (%) | | | |
| Solvent (%) | — | 1-90 | — |
| Binder (%) | — | 20-95 | 2-6 |
| Viscosity Modifier (%) | — | — | 0.01-5 |
| Clearcoat Viscosity @25° C. (cP) | 250-8000 | 25-200 | 200-1000 |
| Activator Viscosity @25° C. (cP) | — | 5-100 | — |
| Clearcoat Calculated VOC (g) | 20-80 | 6-24 | 2-10 |
| Activator Calculated VOC (g) | 6-30 | 2-8 | — |
| Clearcoat Density (g/mL) | 1-2 | 0.7-3 | 0.75-3 |
| Activator Density (g/mL) | 0.5-2 | 0.7-3 | — |
| Clearcoat Solid content (w/w) (%) | 0.25-1 | 30-120 | 25-100 |
| Activator Solid content (w/w) (—) | <5 | 30-120 | — |

Fourth, fifth, sixth, and seventh EMI coatings were created per Table 2 below.

TABLE 2

| Shielding Sample | Fourth | Fifth | Sixth | Seventh |
|---|---|---|---|---|
| Metal Based Conductive | 5-90 | 5-90 | 5-90 | 5-90 |
| Additive (%) | | | | |
| Carbon Based | 0.01-5 | 0.01-5 | 0.01-5 | 0.01-5 |
| Conductive Additive (%) | | | | |
| Binder (%) | 20-95 | 20-95 | 20-95 | 20-95 |
| Viscosity Modifier (%) | 1-90 | — | — | 1-90 |

The fourth EMI shielding coating was made by combining a first part of the binder, a second part of the binder, the metal-based conductive additive, and the carbon-based conductive additive using a mechanical stirrer at a speed of about 6,0000 rpm to about 8,000 for a period of time of about 1 minute to about 10 minutes. After adding the viscosity modifier, the fourth EMI shielding coating was further stirred at a speed of about 100 rpm to about 250 rpm for about 15 minutes to about 60 minutes.

The fifth EMI shielding coating was made by combining the binder, the metal-based conductive additive, and the carbon-based conductive additive, and hand shaking the combined components for a period of time of about 1 minute to about 10 minutes. Thereafter the viscosity modifier was added. Water was added to adjust the consistency of the paint for optimal spraying conditions.

The sixth EMI shielding coating was made by combining the binder, the metal-based conductive additive, and the carbon-based conductive additive, and agitating the combined components for a period of time of about 15 minutes to about 60 minutes. Thereafter the viscosity modifier was added. Water was added to adjust the consistency of the paint for optimal spraying conditions.

The seventh EMI shielding coating was made by combining a first part of the binder, a second part of the binder, a first portion the metal-based conductive additive, and the carbon-based conductive additive using a mechanical stirrer at a speed of about 100 rpm to about 250 rpm for a period of time of about 5 minutes to about 20 minutes. After adding the viscosity modifier, the fourth EMI shielding coating was further stirred at a speed of about 6,000 rpm to about 8,000 rpm for about 1 minute to about 10 minutes. After adding a second portion the metal-based conductive additive, the solution was mixed at a speed of about 100 rpm to about 250 rpm for a period of time of about 1 minute to about 10 minutes. 5 min at 150-200 rpm

### Certain Embodiments of EMI Shields

First, second, and third shielding samples using the were created from the EMI coating described in Table 1 above, per Table 3 below and were tested for shielding effectiveness using the apparatus described herein.

TABLE 3

| Shielding Sample | First | Second | Third |
|---|---|---|---|
| Mix ratio (v/v) (—) | 10:1-3:1 | 1:3-3:1 | — |
| Pot life at 25° C. (hr) | 0.5-2 | 1-4 | — |
| Respray time (min) | 30-120 | 12-60 | 5-30 |
| Dry touch cure time @ 20° C. | 30-120 | 600-2400 | 10-40 |
| (min) | | | |
| Dry touch cure time @ 50° C. | 15-60 | 10-40 | — |
| (min) | | | |
| Light Duty (days) | 1-6 | — | — |
| Full Cure (days) | 2-15 | — | — |
| Sheet thickness (um) | 2.5 | — | 1.5 |
| Sheet resistance (Ω/sq) | 0.02-0.1 | 0.1-0.4 | 0.02-0.1 |
| Conductivity (S/cm) | 1000-3000 | 500-2500 | 1200-5000 |
| Attenuation range at 10 kHz to | 6-80 | 20-150 | 20-180 |
| 400 kHz (dB) | | | |
| Attenuation range at 500 kHz to | 8.33-44.34 | 40.3-74.2 | 42.8-75.5 |
| 30 MHz (dB) | | | |
| Attenuation range at 40 MHz to | 8-150 | 25-150 | 25-140 |
| 1 GHz (dB) | | | |
| Attenuation range at 2 GHz to | 25-200 | 25-150 | 25-140 |
| 18 GHz (dB) | | | |
| Attenuation range at 19 GHz to | 30-200 | 30-200 | 40-200 |
| 40 GHz (dB) | | | |
| Density (g/cm3) | 0.9-3 | 0.9-3 | 0.7-3 |
| Operating Temperature (C.) | <85 | <120 | <90 |
| Electric conductivity (dry film) | 500-3000 | 500-3000 | 1200-3600 |
| (S/m) | | | |
| Thermal conductivity (dry film) | — | 1.5-5 | — |
| (—) | | | |
| Theoretical coverage (mL/sq ft) | 10-30 | 5-20 | 2.5-10 |
| Sheet resistance (Ω/sq) | 0.02-0.1 | 0.1-.4 | .02-.1 |

Fourth, fifth, sixth, and seventh shielding samples were created with the EMI coating samples of Table 2 above, per Table 4 below, and were tested for shielding effectiveness using the apparatus described herein.

TABLE 4

| Shielding Sample | Fourth | Fifth | Sixth | Seventh | Eighth |
|---|---|---|---|---|---|
| Sheet thickness | 85-95 | 95-105 | 40-50 | 95-105 | 40-50 |
| (um) | | | | | |
| Sheet resistance | 0.3-0.4 | 0.03-0.05 | 0.5-0.6 | 0.06 | 0.20 |
| (Ω/sq) | | | | | |
| Conductivity (S/cm) | 336 | 2381 | 393 | 1798 | 1150 |
| Attenuation range at | 65-101 | 48-80 | — | 12-42 | 47-74 |
| 10 kHz to 400 kHz | | | | | |
| (dB) | | | | | |
| Attenuation range at | 76-104 | 75-43 | — | 8-44 | 40-74 |
| 500 kHz to 30 MHz | | | | | |
| (dB) | | | | | |
| Attenuation range at | 54-88.8 | 52-71 | 57-75 | 16-74 | 50-69 |
| 40 MHz to 1 GHz | | | | | |
| (dB) | | | | | |
| Attenuation range at | 43-74 | 43-80 | 60-94 | 50-91 | 50-74 |
| 2 GHz to 18 GHz | | | | | |
| (dB) | | | | | |
| Attenuation range at | 64-82 | 78-103 | 80-91 | 68-90 | 70-105 |
| 19 GHz to 40 GHz | | | | | |
| (dB) | | | | | |

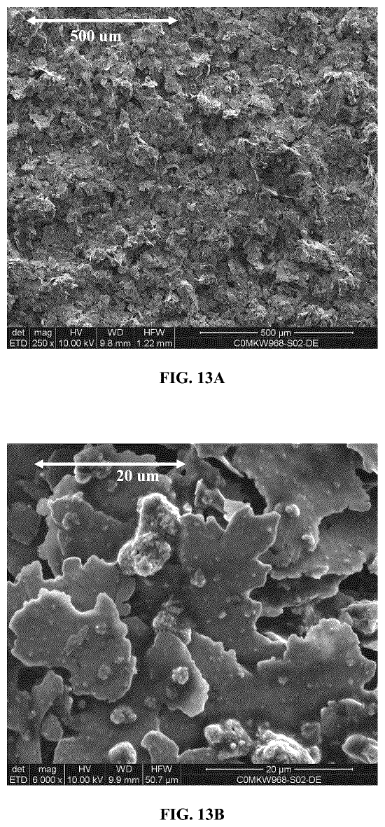

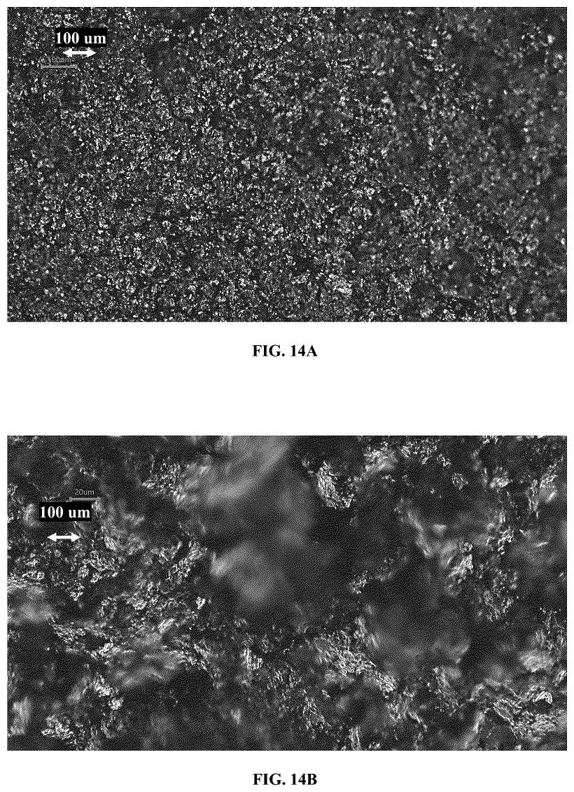

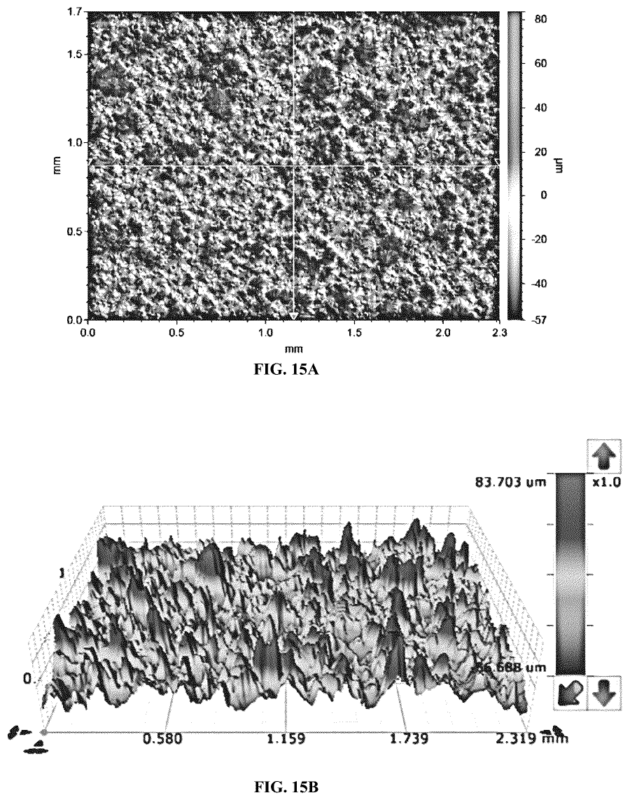

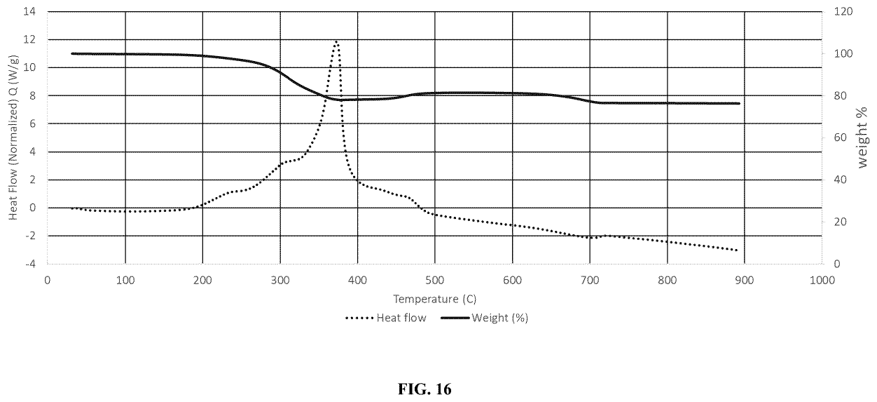

The fourth exemplary shielding sample was formed by spraying multiple coats of the fourth exemplary EMI coating on a substrate, curing the EMI coating on the substrate for about 15 minutes to about 30 minutes at a temperature of about 120° F. to about 160° F., and drying the EMI coating on the substrate at room temperature for a time of about 0.5 days to about 21 days. FIGS. 13A-13B show low and high magnification scanning electron microscope (SEM) images of an exemplary fourth EMI shield. FIGS. 14A-14B show low and high magnification microscope images of an exemplary fourth EMI shield. FIGS. 15A-15B show two-dimensional and three-dimensional height maps of an exemplary fourth EMI shield. FIG. 16 shows a graph of heat flow and weight of an exemplary fourth EMI shield as a function of temperature.

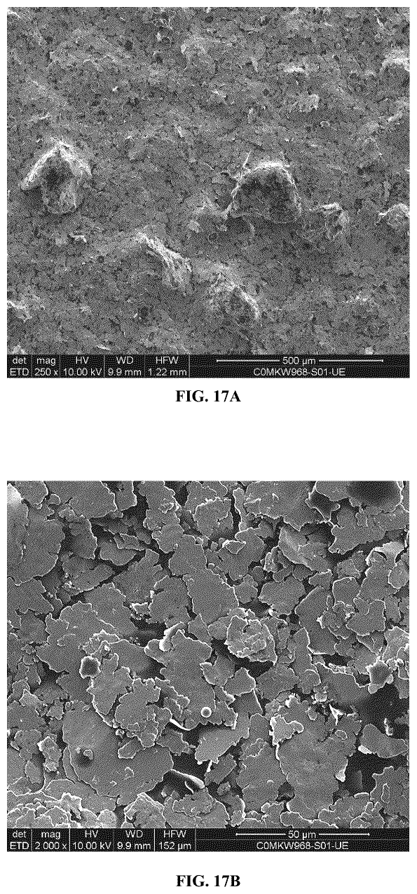

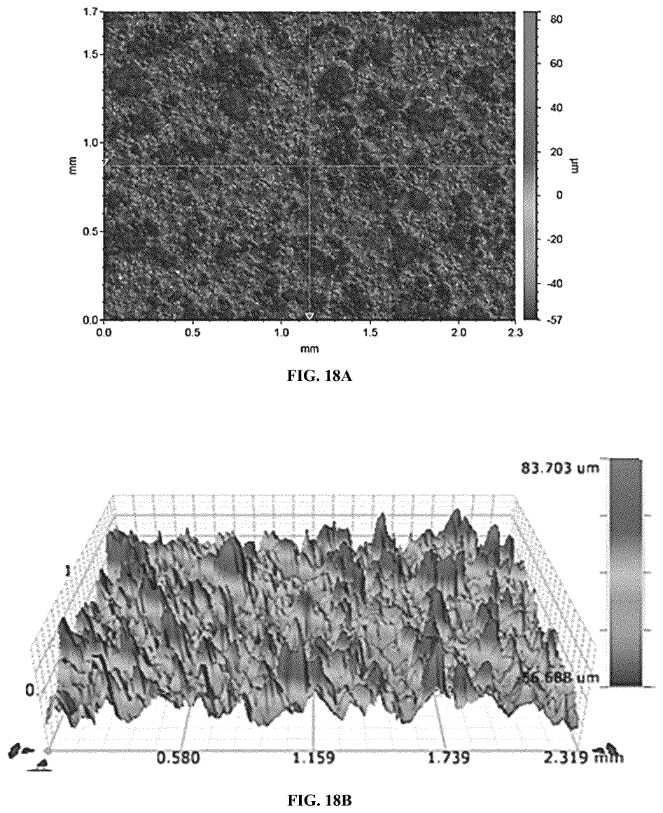

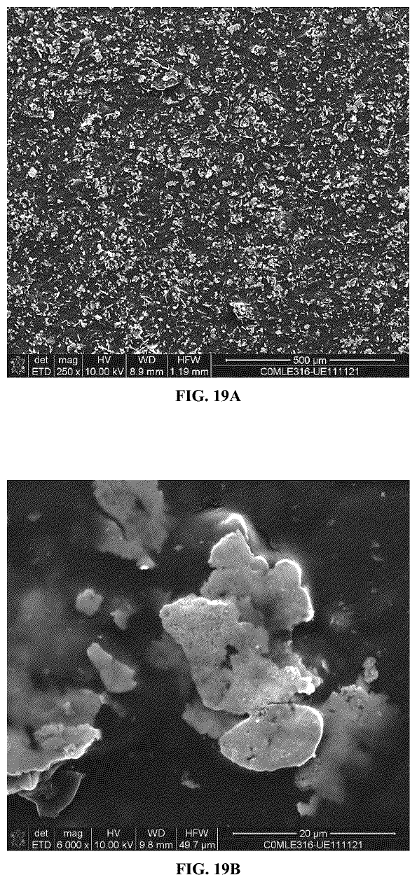

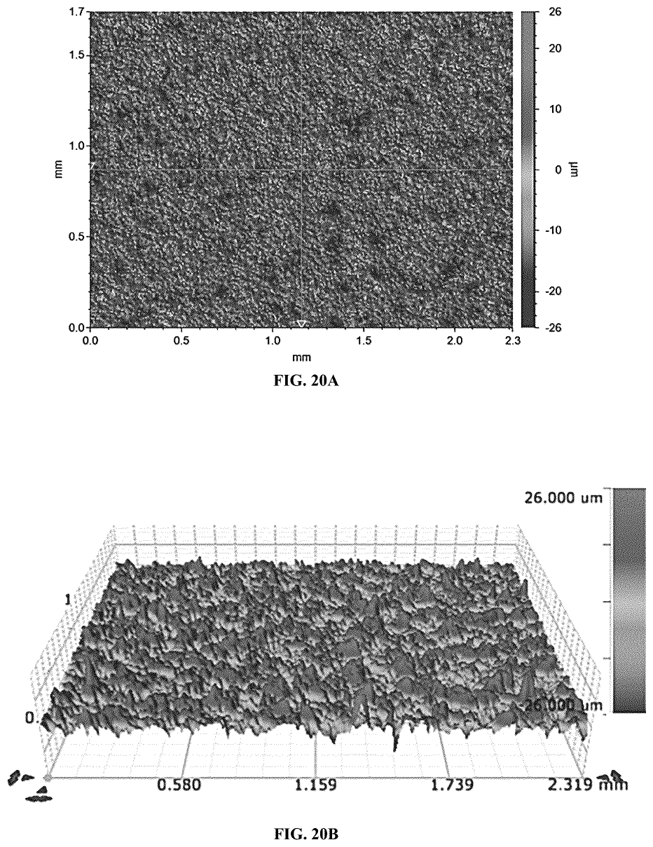

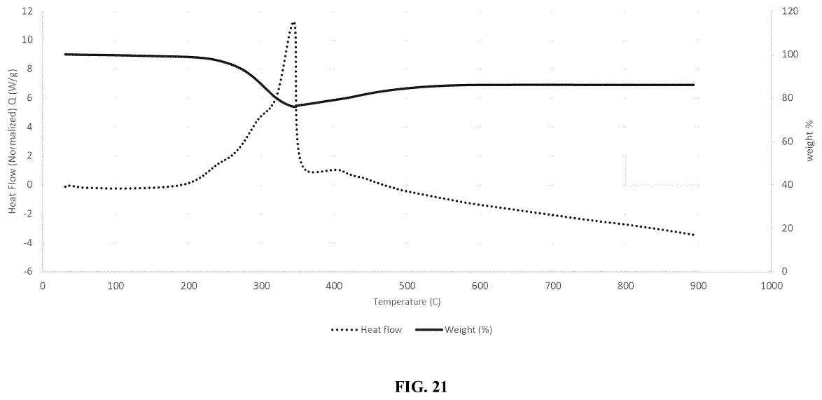

The fifth exemplary shielding sample was formed by air spray the fifth exemplary EMI coating on a substrate. FIGS. 17A-17B show low and high magnification scanning electron microscope (SEM) images of the exemplary fifth EMI shield. FIGS. 18A-18B show two-dimensional and three-dimensional height maps of an exemplary fifth EMI shield. FIG. 21 shows a graph of heat flow and weight of the exemplary fifth EMI shield as a function of temperature. FIGS. 19A-19B show low and high magnification scanning electron microscope (SEM) images of an exemplary EMI shield formed by applying the fifth exemplary EMI coating on a substrate with a doctors blade. FIGS. 20A-20B show two-dimensional and three-dimensional height maps of an exemplary EMI shield formed by applying the fifth exemplary EMI coating on a substrate with a doctors blade. FIG. 21 shows a graph of heat flow and weight of an exemplary fifth EMI shield as a function of temperature.

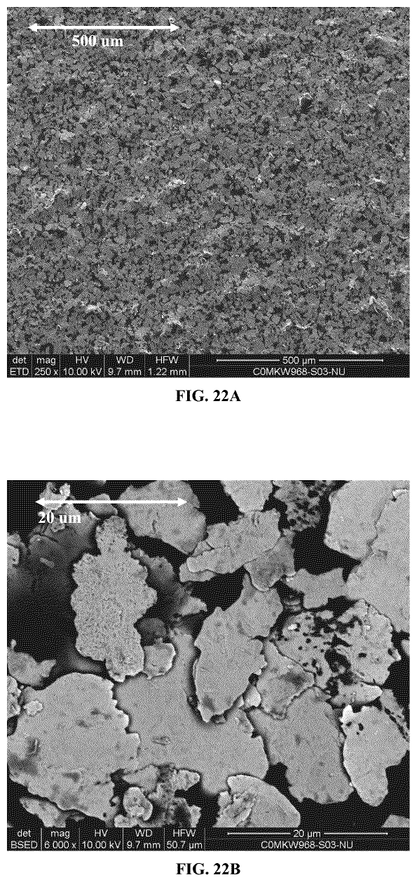

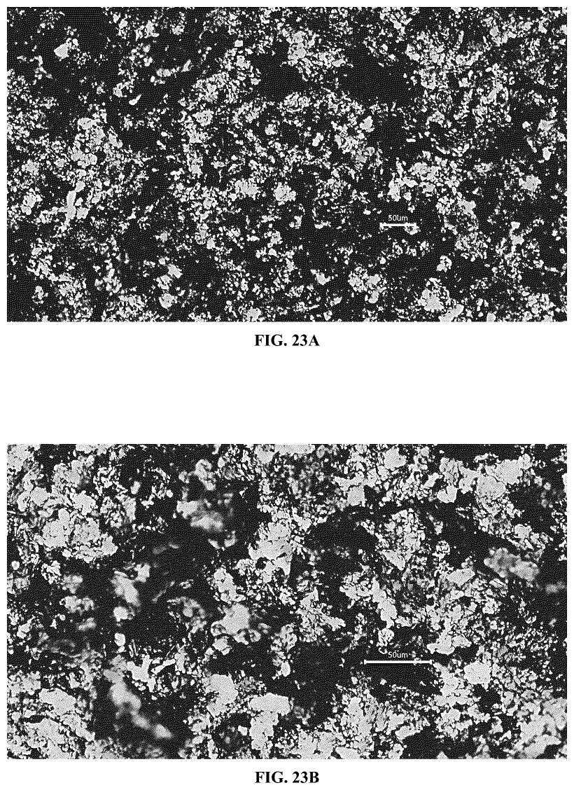

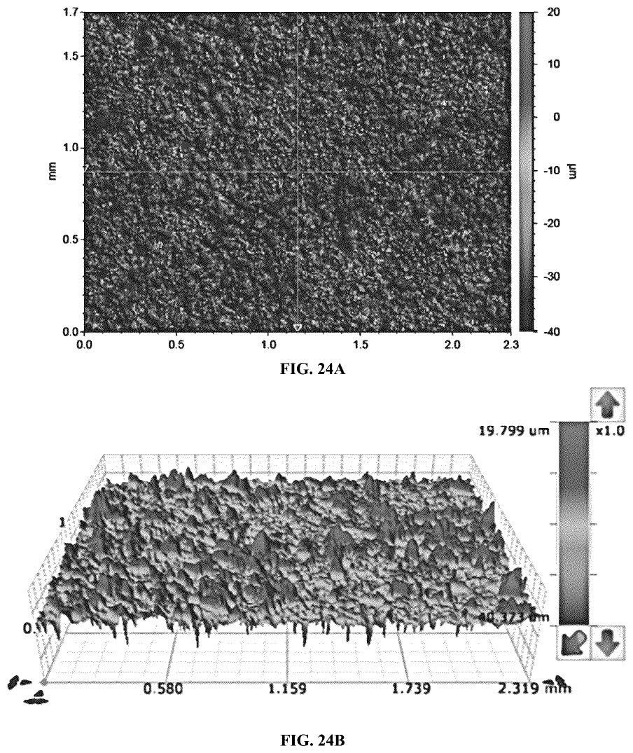

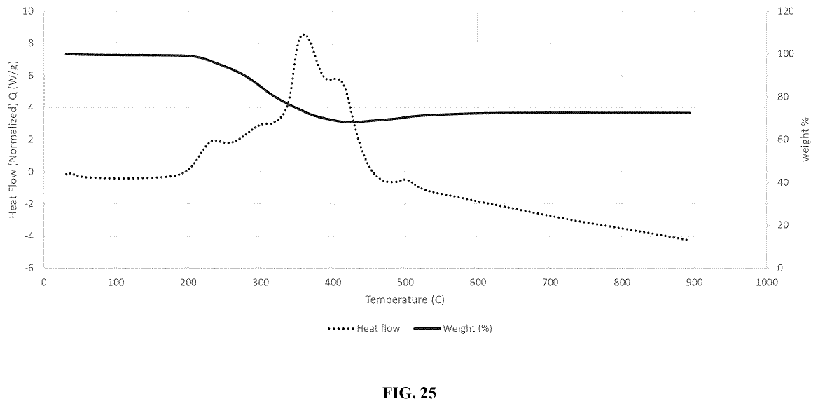

The sixth exemplary shielding sample was formed by applying the sixth exemplary EMI coating to a substrate with a tabletop coater. FIGS. 22A-22B show low and high magnification scanning electron microscope (SEM) images of the exemplary sixth EMI shield. FIGS. 23A-23B show low and high magnification microscope images of the exemplary sixth EMI shield. FIGS. 24A-24B show two-dimensional and three-dimensional height maps of the exemplary sixth EMI shield. FIG. 25 shows a graph of heat flow and weight of the exemplary sixth EMI shield as a function of temperature.

The seventh exemplary shielding sample was formed by applying the seventh exemplary EMI coating to a substrate with a doctor's blade. The eighth exemplary shielding sample was formed by spraying multiple coats of the seventh exemplary EMI coating on a substrate, wherein the seventh exemplary EMI coating is dried by a heat lamp for about 15 minutes to about 60 minutes between each layer. Thereafter, the EMI coating on the substrate was cured for about 15 minutes to about 60 minutes at a temperature of about 120° F. to about 160° F., and dried at room temperature for a time of about 0.5 days to about 21 days.

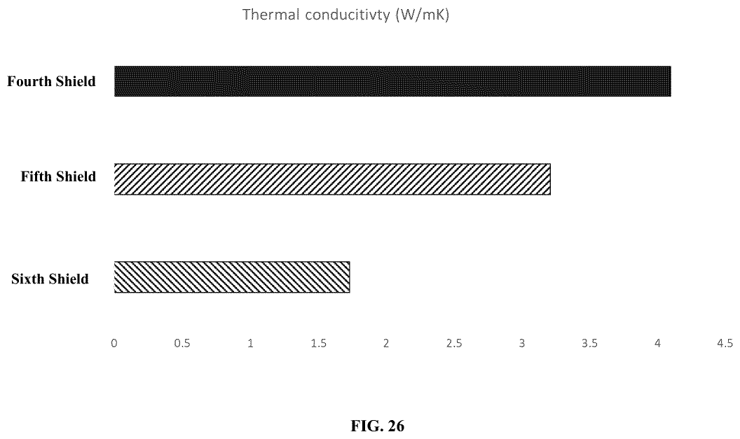

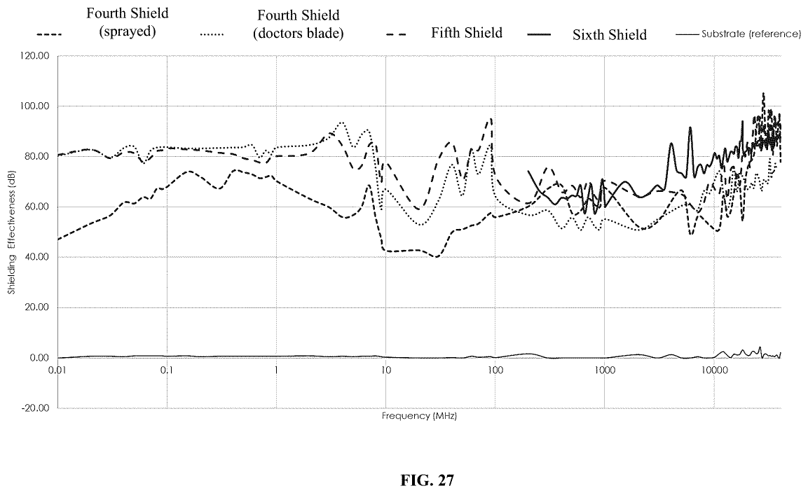

FIG. 26 shows a graph of the conductivities of exemplary fourth, fifth, and sixth EMI shield samples. FIG. 27 shows a graph of the shielding effectiveness vs. frequency for exemplary fourth, fifth, and sixth EMI shield samples.

### Terms and Definitions

Unless otherwise defined, all technical terms used herein have the same meaning as commonly understood by one of ordinary skill in the art to which this disclosure belongs.

As used herein, the singular forms “a,” “an,” and “the” include plural references unless the context clearly dictates otherwise. Any reference to “or” herein is intended to encompass “and/or” unless otherwise stated.

As used herein, the term “about” refers to an amount that is near the stated amount by 10%, 5%, or 1%, including increments therein.

As used herein, the term “about” in reference to a percentage refers to an amount that is greater or less the stated percentage by 10%, 5%, or 1%, including increments therein.

As used herein, the phrases “at least one”, “one or more”, and “and/or” are open-ended expressions that are both conjunctive and disjunctive in operation. For example, each of the expressions “at least one of A, B and C”, “at least one of A, B, or C”, “one or more of A, B, and C”, “one or more of A, B, or C” and “A, B, and/or C” means “A alone, B alone, C alone, A and B together, A and C together, B and C together, or A, B and C together”.

While preferred embodiments of the present disclosure have been shown and described herein, it will be obvious to those skilled in the art that such embodiments are provided by way of example only. Numerous variations, changes, and substitutions will now occur to those skilled in the art without departing from the disclosure. It should be understood that various alternatives to the embodiments of the disclosure described herein may be employed in practicing the disclosure.

What is claimed is:

1. An EMI shield comprising:
a) a substrate;
b) a metal-based conductive additive; and
c) a binder incorporated with the metal-based conductive additive and deposited as an EMI shielding coating on the substrate.

2. The EMI shield of claim 1, wherein the metal-based conductive additive is a metallic nanomaterial comprising nickel, copper, silver, nickel, zinc, aluminum, tin, or gold.

3. The EMI shield of claim 2, wherein the metallic nanomaterial comprises a first metal forming a metallic core and a second metal forming a coating around the metallic core.

4. The EMI shield of claim 3, wherein the first metal comprises aluminum, nickel, copper, or iron, and the second metal comprises silver.

5. The EMI shield of claim 2, wherein the metallic nanomaterial comprises a morphology comprising nanoparticles, nanorods, nanowires, nanoflowers, nanoflakes, nanofibers, nanoplatelets, nanoribbons, nanocubes, bipyramids, nanodiscs, nanoplates, nanodendrites, nanoleaves, nanospheres, quantum spheres, quantum dots, nanosprings, nanosheets, porous nanosheets, nanomesh, or any combination thereof.

6. The EMI shield of claim 1, wherein a w/w concentration of the metal-based conductive additive in the EMI shielding coating is about 5% to about 95%.

7. The EMI shield of claim 1, wherein a w/w concentration of the binder in the EMI shielding coating is about 20% to about 95%.

8. The EMI shield of claim 1, wherein binder comprises an alkyd, an acrylic, a vinyl-acrylic, vinyl acetate/ethylene (VAE), polyurethane, polyethylene, polyester, styrene, styrene acrylic, melamine, a silane, a siloxane, or any combination thereof.

9. The EMI shield of claim 1, wherein the EMI shielding coating further comprises a coating thinner.

10. The EMI shield of claim 9, wherein the coating thinner comprises acetone, 4-chloro-alpha, alpha, alpha-trifluorotoluene, acetone, or any combination thereof.

11. The EMI shield of claim 9, wherein a w/w concentration of the coating thinner in the EMI shielding coating is about 5% to about 90%.

12. The EMI shield of claim 1, wherein the EMI shielding coating further comprises a viscosity modifier.

13. The EMI shield of claim 12, wherein the viscosity modifier comprises Acetone, N-Methyl-2-pyrrolidone (NMP), Ethanol, Xylene, Petroleum, N-butyl acetate, Heptan-2-one, 4-isocyanatosulphonyltoluene, 2-Methoxy-1-methylethyl acetate, or combinations thereof.

14. The EMI shield of claim 1, further comprising a carbon-based additive.

15. The EMI shield of claim 14, wherein a w/w concentration of the carbon-based additive in the EMI shielding coating is about 0.01% to about 5%.

16. The EMI shield of claim 14, wherein the carbon-based additive comprises graphite, graphene, reduced graphene, carbon black, cabot carbon, a carbon nanotube, a functionalized carbon nanotube, or any combination thereof.

17. AN EMI shielding coating comprising:
a) a metal-based conductive additive;
b) a binder; and
c) a solvent incorporated with the metal-based conductive additive and binder to form the EMI shielding coating.

18. The EMI shielding coating of claim 17, wherein the EMI shielding coating comprises a clearcoat coating and an activator coating, wherein mixing the clearcoat coating and the activator coating causes the EMI shielding coating to cure.

19. The EMI shielding coating of claim 17, wherein the metal-based conductive additive is a metallic nanomaterial comprising nickel, copper, silver, nickel, zinc, aluminum, tin, or gold.

20. The EMI shielding coating of claim 19, wherein the metallic nanomaterial comprises a first metal forming a metallic core and a second metal forming a coating around the metallic core.

21. The EMI shielding coating of claim 20, wherein the first metal comprises aluminum, nickel, copper, or iron, and the second metal comprises silver.

22. The EMI shielding coating of claim 19, wherein the metallic nanomaterial comprises a morphology comprising nanoparticles, nanorods, nanowires, nanoflowers, nanoflakes, nanofibers, nanoplatelets, nanoribbons, nanocubes, bipyramids, nanodiscs, nanoplates, nanodendrites, nanoleaves, nanospheres, quantum spheres, quantum dots, nanosprings, nanosheets, porous nanosheets, nanomesh, or any combination thereof.

23. The EMI shielding coating of claim 17, wherein a w/w concentration of the metal-based conductive additive in the EMI shielding coating is about 5% to about 95%.

24. The EMI shielding coating of claim 17, wherein a w/w concentration of the binder in the EMI shielding coating is about 20% to about 95%.

25. The EMI shielding coating of claim 17, wherein binder comprises an alkyd, an acrylic, a vinyl-acrylic, vinyl acetate/ethylene (VAE), polyurethane, polyethylene, polyester, styrene, styrene acrylic, melamine, a silane, a siloxane, or any combination thereof.

26. The EMI shielding coating of claim 17, wherein the EMI shielding coating further comprises a coating thinner.

27. The EMI shielding coating of claim 26, wherein the coating thinner comprises acetone, 4-chloro-alpha, alpha, or alpha-trifluorotoluene, acetone, or any combination thereof.

28. The EMI shielding coating of claim 26, wherein a w/w concentration of the coating thinner in the EMI shielding coating is about 5% to about 90%.

29. The EMI shielding coating of claim 17, wherein the EMI shielding coating further comprises a viscosity modifier.

30. The EMI shielding coating of claim 29, wherein the viscosity modifier comprises Acetone, N-Methyl-2-pyrrolidone (NMP), Ethanol, Xylene, Petroleum, N-butyl acetate, Heptan-2-one, 4-isocyanatosulphonyltoluene, 2-Methoxy-1-methylethyl acetate, or combinations thereof.

31. The EMI shielding coating of claim 17, further comprising a carbon-based additive.

32. The EMI shielding coating of claim 31, wherein a w/w concentration of the carbon-based additive in the EMI shielding coating is about 0.01% to about 5% w/w.

33. The EMI shielding coating of claim 31, wherein the carbon-based additive comprises graphite, graphene, reduced graphene, carbon black, cabot carbon, a carbon nanotube, a functionalized carbon nanotube, or any combination thereof.

34. The EMI shielding coating of claim 17, wherein the EMI shielding coating has a thickness of less than about 150 um.

35. A method of forming an EMI shield comprising:
a) forming a coating comprising a metal-based conductive additive, a binder, and a solvent;
b) depositing the coating on a substrate; and
c) drying the coating on the substrate to form an EMI shielding coating.

36. The method of claim 35, wherein a set thickness of the coating is deposited on the substrate.

37. The method of claim 35, wherein drying the coating on the substrate comprises drying at a temperature of about 20° C. to about 120° C.

38. The method of claim 35, wherein the forming of the coating comprises:
a) mixing the coating;
b) breaking down agglomerates in the coating;
c) removing air bubbles from the coating; or
d) any combination thereof.

39. The method of claim 38, wherein the mixing is performed by an acoustic mixer.

40. The method of claim 38, wherein the breaking down of the agglomerates in the coating is performed by a high shear mixer.

41. The method of claim 38, wherein the removing of the air bubbles from the coating is performed by a vacuum mixer.

42. The method of claim 35, wherein depositing the coating on a substrate comprises depositing the coating on the substrate with a coating machine.

43. The method of claim 42, wherein the coating machine is a slot die coating machine.

44. The method of claim 38, wherein at least one of the breaking down of the agglomerates in the coating and the removing of the air bubbles from the coating is performed until the coating has a viscosity of about 25 cP to about 8,000 cP.

45. The method of claim 35, wherein the coating has a viscosity of about 25 cP to about 8,000 cP.

46. The method of claim 35, further comprising calendaring the EMI shield.

47. The method of claim 46, wherein calendaring is performed by a roll to roll calendaring machine.
